(19) United States
(12) Patent Application Publication
(10) Pub. No.: US 2025/0364429 A1
(43) Pub. Date: Nov. 27, 2025

(54) SEMICONDUCTOR DEVICE INCLUDING OVERLAY KEYS AND METHOD OF MANUFACTURING THE SAME

(71) Applicant: SK hynix Inc., Gyeonggi-do (KR)

(72) Inventor: Heon Yong CHANG, Gyeonggi-do (KR)

(21) Appl. No.: 19/083,442

(22) Filed: Mar. 19, 2025

(30) Foreign Application Priority Data
May 22, 2024 (KR) 10-2024-0066757

(51) Int. Cl. H01L 23/544; H10B 12/00

(52) U.S. Cl. CPC H01L 23/544; H10B 12/02; H10B 12/482; H10B 12/485; H10B 12/488; H01L 2223/54426

(57) ABSTRACT

A semiconductor device including overlay keys and a method of manufacturing the device are provided. The semiconductor device includes first, second, third, and fourth pattern arrays. The first pattern array includes first conductive patterns and first overlay key segments. The second pattern array includes second overlay key segments and third overlay key segments. The third pattern array includes third conductive patterns and fourth overlay key segments. The fourth pattern array includes fifth overlay key segments and sixth overlay key segments. The first, second, third, fourth, fifth, and sixth overlay key segments provide alignment information of the fourth pattern array with respect to the first, second, and third pattern arrays.

### CROSS-REFERENCE TO RELATED APPLICATIONS

The present application claims priority under 35 U.S.C. 119(a) to Korean Patent Application No. 10-2024-0066757, filed on May 22, 2024, which is incorporated herein by reference in its entirety.

### BACKGROUND

### 1. Technical Field

Embodiments of the present disclosure generally relate to an integrated circuit device and, more particularly, to a semiconductor device including overlay keys and a method of manufacturing the same.

### 2. Related Art

A semiconductor device may be formed by integrating integrated circuits (ICs) on a semiconductor substrate or a semiconductor wafer. A semiconductor device may include a connection structure in which multi-layered conductive patterns may be connected to each other. However, as sizes and critical dimensions (CDs) of the conductive patterns are reduced, alignment accuracy or overlay accuracy between the conductive patterns becomes more challenging. Generally, preceding patterns may be formed earlier than subsequent patterns, and the degree of alignment in which the subsequent patterns are aligned with respect to the preceding patterns may be measured using overlay keys.

### SUMMARY

An embodiment of the present disclosure is directed to a semiconductor device including a first pattern array including first conductive patterns and first overlayer key segments over a semiconductor substrate, a second pattern array including second conductive patterns, second overlay key segments, and third overlay key segments, a third pattern array including third conductive patterns and fourth overlay key segments, and a fourth pattern array including fourth conductive patterns, fifth overlay key segments, and sixth overlay key segments. The first, second, third, fourth, fifth, and sixth overlay key segments provide alignment of the fourth conductive patterns relative to the first, second, and third conductive patterns.

According to another embodiment of the present disclosure a semiconductor device may include a first pattern array including first conductive patterns and first overlayer key segments over a semiconductor, the first conductive patterns extending in a first direction and spaced apart from each other along a second direction intersecting the first direction, and the first overlay key segments spaced apart from each other along the second direction, a second pattern array including second conductive patterns, second overlay key segments and third overlay key segments, the second overlay key segments spaced apart from each other along the first direction, and the third overlay key segments spaced apart from each other along the second direction, a third pattern array including third conductive patterns and fourth overlay key segments, the third conductive patterns extending in the second direction and spaced apart from each other along the first direction, and the fourth overlay key segments spaced apart from each other along the first direction, a sixth pattern array including sixth conductive patterns, ninth overlay key segments, and tenth overlay key segments, the sixth conductive patterns passing between the third conductive patterns and connecting to some portions of the semiconductor substrate, the ninth overlay key segments spaced apart from each other along the first direction, and the tenth overlay key segments spaced apart from each other along the second direction, and a fourth pattern array including fourth conductive patterns, fifth overlay key segments, and sixth overlay key segments, each of the fourth conductive patterns connected to the first, second, third, and sixth conductive patterns and a portion of the semiconductor substrate, the fifth overlay key segments spaced apart from each other along the first direction, and the sixth overlay key segments spaced apart from each other along the second direction. The first, second, third, fourth, fifth, sixth, ninth, and tenth overlay key segments provide alignment of the fourth conductive patterns relative to the first, second, third, and sixth conductive patterns.

Yet another embodiment of the present disclosure is directed to a method of manufacturing a semiconductor device. The method includes forming a first pattern array over a semiconductor substrate, the first pattern array including first conductive patterns and first overlayer key segments, forming a second pattern array including second conductive patterns, second overlay key segments and third overlay key segments, forming a third pattern array including third conductive patterns and fourth overlay key segments, and forming a fourth pattern array including fourth conductive patterns, fifth overlay key segments, and sixth overlay key segments. The first, second, third, fourth, fifth, and sixth overlay key segments provide alignment of the fourth conductive patterns relative to the first, second, and third conductive patterns.

These and other features and advantages of the embodiments of the present disclosure will become apparent from the following drawings and detailed description.

### BRIEF DESCRIPTION OF THE DRAWINGS

FIG. 1 is a schematic view illustrating a semiconductor device according to an embodiment of the present disclosure.

FIG. 2 through FIG. 8 are schematic diagrams illustrating active regions of a semiconductor device according to an embodiment of the present disclosure.

FIG. 9 through FIG. 13 are schematic diagrams illustrating a first pattern array of a semiconductor device according to an embodiment of the present disclosure.

FIG. 14 through FIG. 35 are schematic diagrams illustrating a second pattern array of a semiconductor device according to an embodiment of the present disclosure.

FIG. 36 through FIG. 41 are schematic diagrams illustrating a third pattern array of a semiconductor device according to an embodiment of the present disclosure.

FIG. 42 through 48 are schematic diagrams illustrating a fourth pattern array of a semiconductor device according to an embodiment of the present disclosure.

FIG. 49 through 55 are schematic diagrams illustrating a fifth pattern array of a semiconductor device according to an embodiment of the present disclosure.

FIG. 56 through FIG. 60 are schematic diagrams illustrating a sixth pattern array of a semiconductor device according to an embodiment of the present disclosure.

FIG. 61 through FIG. 70 are schematic diagrams illustrating a fourth pattern array of a semiconductor device according to an embodiment of the present disclosure.

FIG. 71 through 78 are schematic diagrams illustrating a fifth pattern array of a semiconductor device according to an embodiment of the present disclosure.

FIG. 79 is a schematic diagram illustrating measurement of alignment information in a semiconductor device according to an embodiment of the present disclosure.

### DETAILED DESCRIPTION

The terms used herein may correspond to words selected in consideration of their functions in the presented embodiments, and the meanings of the terms may be construed to be different according to ordinary skill in the art to which the embodiments belong. If defined in detail, the terms may be construed according to the definitions. Unless otherwise defined, the terms used herein have the same meaning as commonly understood by one of ordinary skill in the art to which the embodiments belong.

In the description of the present disclosure, descriptions such as “first,” “second” and “third,” “upper” and “lower,” “upper” and “lower,” “Preceding” and “succeeding” are used for distinguishing elements, and are not used to limit the elements themselves or to imply a specific order.

The embodiments of the present disclosure can be applied to the field of technology that implements integrated circuit devices such as DRAM, NAND FLASH, PCRAM, or ReRAM devices. In addition, the embodiments of the present disclosure can also be applied to the field of technology that implements memory devices storing data or logic devices performing logical operations. The embodiments of the present disclosure can be applied to the field of technology that implements various products that require fine-sized conductive lines or conductive patterns.

The same reference numerals refer to the same device elements throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

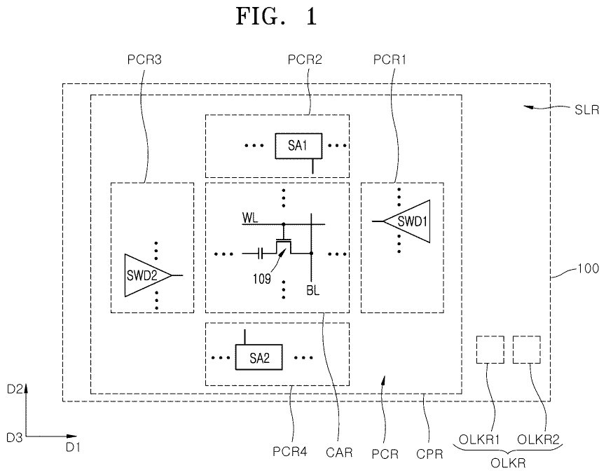

FIG. 1 is a schematic view illustrating a semiconductor device according to an embodiment of the present disclosure.

Referring to FIG. 1, the semiconductor device includes at least one cell device 109 and peripheral circuits which are integrated on a semiconductor substrate 100. The semiconductor substrate 100 includes a medium on which various types of integrated circuits are integrated. The semiconductor substrate 100 is a semiconductor wafer. The semiconductor substrate 100 includes a semiconductor material. For example, the semiconductor substrate 100 may be a silicon (Si) substrate, a germanium (Ge) substrate, or a silicon-germanium (SiGe) substrate.

The semiconductor substrate 100 includes distinct regions such as a cell array region CAR, a peripheral circuit region PCR, and an overlay key region OLKR. The semiconductor substrate 100 may include a chip region CPR and a scribe lane region SLR that are distinct from each other. The chip region CPR includes the cell array region CAR and the peripheral circuit region PCR. The chip region may be an area that is divided from the semiconductor substrate 100 to become a semiconductor chip.

The scribe lane region SLR surrounds and demarcates the chip region CPR. The overlay key region OLKR may be disposed in the scribe lane region SLR. Overlay keys are disposed in the overlay key region OLKR. The overlay key region OLKR may include a first overlay key region OLKR1 and/or a second overlay key region LOKR2. Various overlay keys may be disposed over the first and second overlay key regions OLKR1 and OLKR2.

Although one cell device 109 is shown in FIG. 1, the semiconductor device includes a plurality of cell devices 109. The cell devices 109 may be arranged in the cell array region CAR. The cell devices 109 may be memory devices. Each of the memory devices may include a transistor and a data storage device. Each of the memory devices 109 may be a DRAM device. The data storage device may be a capacitor. Word lines WL and bit lines BL may be arranged to be connected to the cell devices 109 in the cell array region CAR.

The bit lines BL cross over the word lines WL in the cell array region CAR. The cell device 109 is disposed at a point where the bit lines BL cross the word lines WL. The word lines WL extend along a first direction D1 in the semiconductor substrate 100, and the bit lines BL extends along a second direction D2. The first direction D1 is a direction intersecting the second direction D2. The first direction D1 may be orthogonal to the second direction D2. A third direction D3 is perpendicular to both the first direction D1 and the second direction D2. The first direction D1 is an X-axis direction, the second direction D2 is a Y-axis direction, and the third direction D3 is a Z-axis direction in an X-Y-Z coordinate system.

The peripheral circuits are disposed in the peripheral circuit region PCR. The peripheral circuits operate the cell devices 109. The peripheral circuits include sub-word line drivers SWD and/or sense amplifiers SA. For example, the sub-word line drivers SWD may be disposed in the left and right sides of the cell array region CAR and connected to the corresponding word lines WL as shown in FIG. 1. First sub-word line drivers SWD1 may be connected to some word lines WL and are disposed in a first peripheral circuit region PCR1. The first peripheral circuit region PCR1 is located on the right side of the cell array region CAR. Second sub-word line drivers SWD2 may be connected to the rest of the word lines WL and are disposed in a third peripheral circuit region PCR3. The third peripheral circuit region PCR3 is located on the left side of the cell array region CAR. The word lines WL may be connected to the first and second sub-word line drivers SWD1 and SWD2 alternately or one by one.

The sense amplifiers SA may be disposed above and below the cell array region CAR and may be connected to the corresponding bit lines BL. First sense amplifiers SA1 may be connected to some bit lines BL and disposed in a second peripheral circuit region PCR2. The second peripheral circuit region PCR2 is located above the cell array region CAR. Second sense amplifiers SA2 may be connected to the rest of the bit lines BL and disposed in a fourth peripheral circuit region PCR4. The fourth peripheral circuit region PCR4 is located below the cell array region CAR. The bit lines BL may be alternately connected to the first and second sense amplifiers SA1 and SA2. Peripheral circuits including row decoders, column decoders, and controllers may be further disposed in the peripheral circuit region PCR.

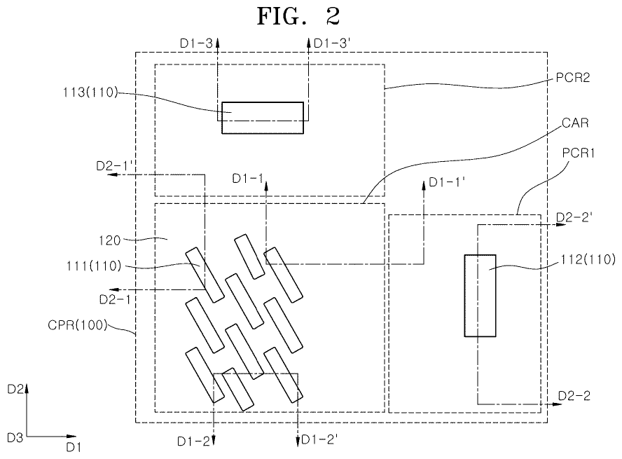

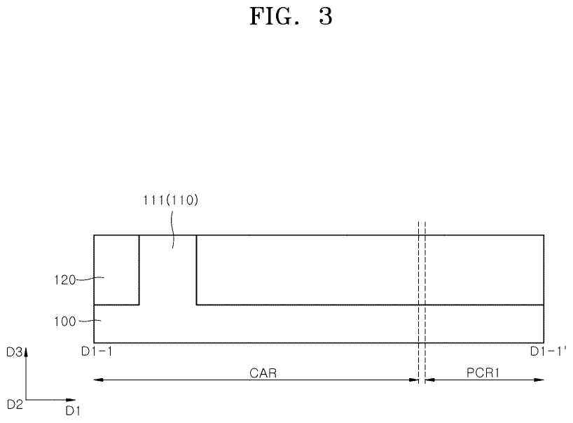

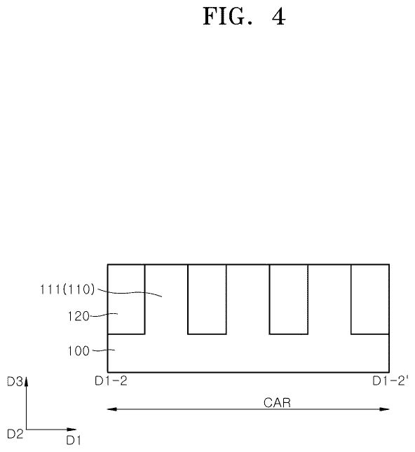

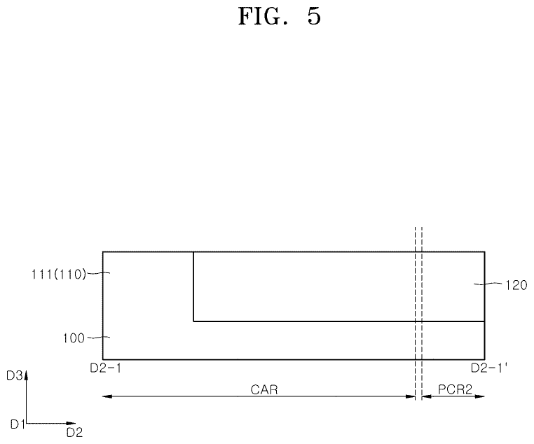

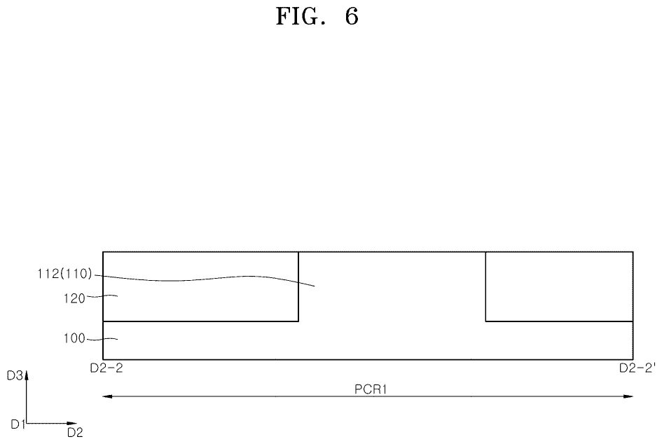

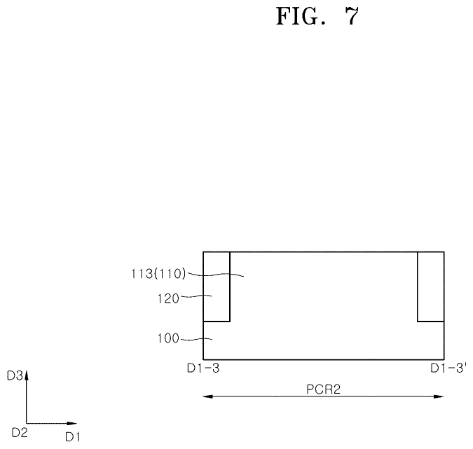

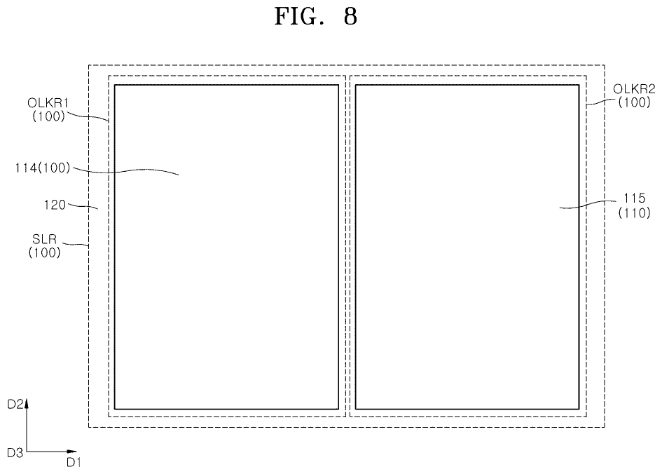

FIG. 2 through FIG. 8 are schematic diagrams illustrating active regions 110 of a semiconductor device according to an embodiment of the present disclosure. FIG. 2 is a schematic plan view illustrating an arrangement of first, second, and third active regions 111, 112, 113 in a chip region CPR of a semiconductor device. FIG. 3 is a schematic view illustrating a cross-sectional shape along a line from D1-1 to D1-1′ in FIG. 2. FIG. 4 is a schematic view illustrating a cross-sectional shape along a line from D1-2 to D1-2′ in FIG. 2. FIG. 5 is a schematic view illustrating a cross-sectional shape along a line from D2-1 to D2-1′ in FIG. 2. FIG. 6 is a schematic view illustrating a cross-sectional shape along a line from D2-2 to D2-2′ in FIG. 2. FIG. 7 is a schematic view illustrating a cross-sectional shape along a line from D1-3 to D1-3′ in FIG. 2. FIG. 8 is a schematic plan view illustrating an arrangement of fourth and fifth active regions 114, 115 in a scribe lane region SLR of a semiconductor device. The chip region CPR of FIG. 2 and the scribe lane region SLR of FIG. 5 may be disposed on a semiconductor substrate 100 to be distinguished from each other as illustrated in FIG. 1.

Referring to FIG. 2, FIG. 3, FIG. 4, FIG. 5, FIG. 6, FIG. 7, and FIG. 8, an isolation region 120 is formed and defines active regions 110 in a semiconductor substrate 100 of a semiconductor device. The isolation region 120 separates and isolates the active regions 110 both physically and electrically from each other. The isolation region 120 consists of insulating material such as silicon oxide, silicon nitride, and/or silicon oxynitride. The active regions 110 are portions or areas of the semiconductor substrate 100 surrounded and partitioned by the isolation region 120.

The semiconductor substrate 100 may be partitioned by the isolation regions 120 such that the active regions 110 have different planar shapes for distinct regions of the semiconductor substrate 100. FIG. 2 may show a planar shape formed on a surface of the semiconductor substrate 100 as viewed from the third direction D3.

Referring to FIG. 2, FIG. 3, FIG. 4, and FIG. 5, the first active regions 111 are located in the cell array region CAR in the chip region CPR of the semiconductor substrate 100. The first active regions 111 are some of the active regions 110. The first active regions 111 may be formed to have a rectangular planar shape or an elliptical planar shape extending in an oblique direction at the surface of the semiconductor substrate 100. The oblique direction may be a direction between the first direction D1 and the second direction D2 on the surface of the semiconductor substrate 100. The first active regions 111 are spaced apart from each other in an oblique direction. As illustrated in FIG. 1 and FIG. 4, the first active regions 111 are spaced apart from each other in the first direction D1 and may also be spaced apart in the second direction D2.

Referring to FIG. 2 and FIG. 6, the second active region 112, which is another part of the active regions 110, is partitioned by the isolation region 120 in the first peripheral circuit region PCR1 in the chip region CPR of the semiconductor substrate 100. The second active region 112 may have a different planar shape than the first active regions 111. The second active region 112 is formed as, but not limited to, a rectangular planar shape extending in the second direction in FIG. 2. Additional active regions may be further located in the first peripheral circuit region PCR1 while being spaced apart from the second active region 112.

Referring to FIG. 2 and FIG. 7, the third active region 113, which is another part of the active regions 110, is partitioned by the isolation region 120 in the second peripheral circuit region PCR2 in the chip region CPR of the semiconductor substrate 100. The third active region 113 is formed as a rectangular planar shape extending in the first direction but is not limited thereto.

Referring to FIG. 2 and FIG. 8, the fourth active region 114, which is another part of the active regions 110, is partitioned by the isolation region 120 in the first overlay key region OLKR1 of the semiconductor substrate 100. The fifth active region 115, which is another part of the active regions 110, is partitioned by the isolation region 120 in the second overlay key region OLKR2 of the semiconductor substrate 100.

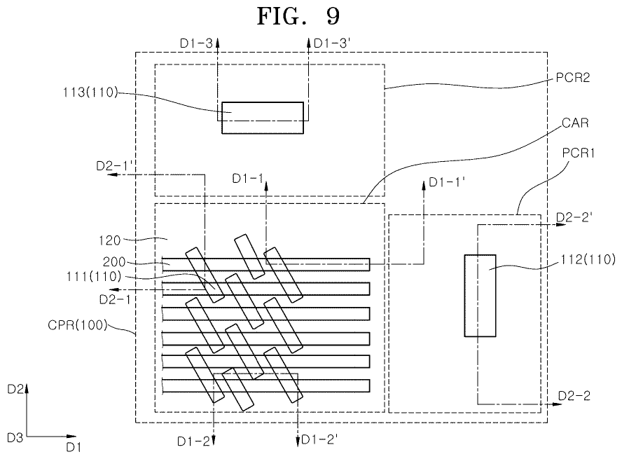

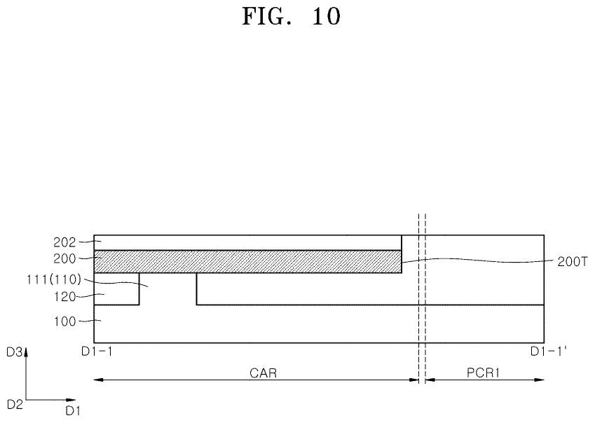

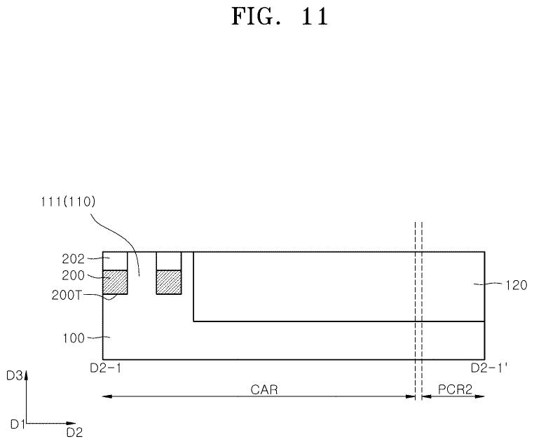

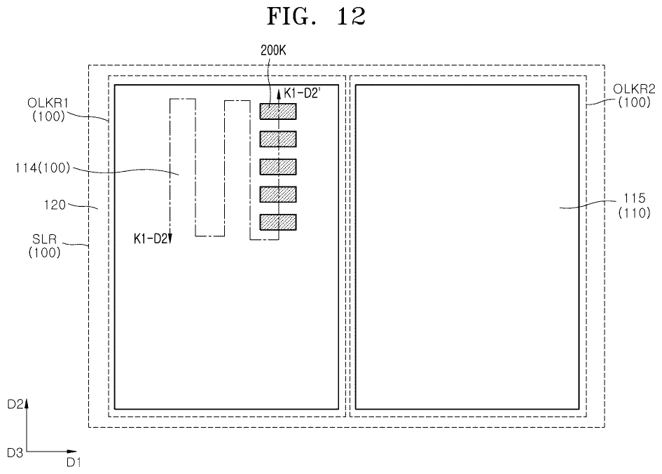

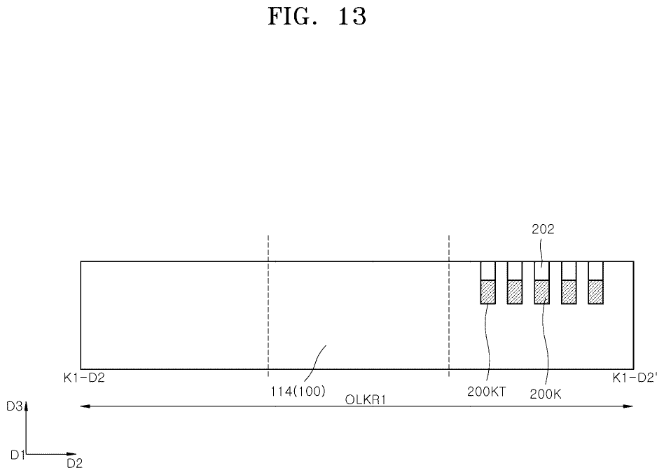

FIG. 9 through FIG. 13 are schematic diagrams illustrating a first pattern array of a semiconductor device according to an embodiment of the present disclosure. FIG. 9 is a schematic plan view illustrating an arrangement of first conductive patterns 200 in a chip region CPR of a semiconductor device. FIG. 10 is a schematic view illustrating a cross-sectional shape along a line from D1-1 to D1-1′ in FIG. 9. FIG. 11 is a schematic view illustrating a cross-sectional shape along a line from D2-1 to D2-1′ in FIG. 9. FIG. 12 is a schematic plan view illustrating first overlayer key segments 200K of a semiconductor device. FIG. 13 is a schematic view illustrating a cross-sectional shape along a line from K1-D2 to K1-D2′ in FIG. 12.

Referring to FIG. 9, FIG. 10, FIG. 11, FIG. 12, and FIG. 13, a first pattern array is formed in the semiconductor substrate 100. In an embodiment, the first pattern array may be formed over the semiconductor substrate 100. Referring to FIG. 9 and FIG. 12, the first pattern array includes first conductive patterns 200 and first overlay key segments 200K. The first overlay key segments 200K are formed simultaneously with the first conductive patterns 200. As the first overlay key segments 200K are formed at the same time as the first conductive patterns 200, the first overlay key segments 200K and the first conductive patterns 200 are located together in the first pattern array. The first overlay key segments 200K and the first conductive patterns 200 are formed in the same patterning process. The patterning process for the first pattern array may include a deposition process, a photolithography process, an etching process, or the like.

Referring to FIG. 9, FIG. 10, and FIG. 11, the first conductive patterns 200 are formed as line and space features in the semiconductor substrate 100. The line features are the actual conductive paths or tracks made of conductive material and which serve as the electrical connections between different components on the semiconductor substrate. The space features are the gaps or spaces between the conductive lines which isolate the conductive lines from each other, preventing electrical short circuits, and ensuring that each line operates independently. The first conductive patterns 200 may extend in the first direction D1 and may be spaced apart from each other along the second direction D2 in the semiconductor substrate 100. The first conductive patterns 200 may be line patterns extending in the first direction D1 side by side. The first conductive patterns 200 are deposed in the cell array region CAR of the semiconductor substrate 100. The first conductive patterns 200 may serve as word lines WL of the cell devices 109 of FIG. 1. The first conductive patterns 200 may be formed as cell gate patterns of cell transistors constituting the cell devices 109 of FIG. 1.

Referring to FIG. 9, FIG. 12, and FIG. 13, the first overlay key segments 200K are located in the first overlay key region OLKR1 in the semiconductor substrate 100. These segments are placed at intervals along a direction parallel to the spacing of the first conductive patterns 200. This means that since the first conductive patterns are spaced apart from each other along a second direction 200, the overlay key segments are also spaced apart in the same direction. In addition, the second direction D2 is typically a vertical direction. The first overlay key segments 200K are also spaced apart from each other in the same vertical direction D2. This arrangement ensures that the overlay key segments are aligned with the conductive patterns in both horizontal and vertical directions. By positioning the overlay key segments in this manner, the alignment of photolithographic masks during the semiconductor manufacturing process is facilitated. This precise alignment ensures accurate layering and positioning of the various components of the semiconductor device, ultimately ensuring its proper function.

The first overlay key segments 200K are formed to have bar features. The first overlay key segments 200K may have a greater width, a greater critical dimension (CD), or/and greater pitches than the first conductive patterns 200. The first overlay key segments 200K act as a first overlay key that provides overlay information or alignment information of the first pattern array.

As the first conductive patterns 200 and the first overlay key segments 200K constituting the first pattern array are formed at the same time, when the first conductive patterns 200 are formed by being shifted or displaced from an intended position in design, the first overlay Key segments 200K are also formed by being moved, shifted, or displaced from the intended position in design. By comparing the positions of the first overlay key segments 200K and the subsequent overlay key segments, overlay information or alignment information between the first conductive patterns 200 and subsequent patterns may be obtained or may be measured.

An image of the first overlay key segments 200K and the subsequent overlay key segments may be obtained using an overlay measurement equipment, and the positions of the first overlay key segments 200K and the following overlay key segments may be compared using the image. Alternatively, the position of the first overlay key segments 200K and the position of the subsequent overlay key segments may be measured by scanning measurement light to the first overlay Key segments 200K and subsequent overlay Key segments.

As the first conductive patterns 200 may extend side by side in the first direction D1 and may be spaced apart from each other in the second direction D2, displacement in the second direction D2 may be more important than displacement in the first direction D1 for overlay measurement or misalignment measurement. When displacement of the first conductive patterns 200 occurs in the first direction D1, as the first conductive patterns 200 may extend in the first direction D1, it is possible for the subsequent patterns to be connected to the first conductive patterns 200. However, when the first conductive patterns 200 are displaced in the second direction D2, as the first conductive patterns 20 are spaced apart from each other in the second direction D2, a failure may occur in connecting the subsequent patterns to the first conductive patterns 200.

Accordingly, the first overlay key segments 200K are formed to be spaced apart from each other in the same direction as a direction in which the first conductive patterns 200 are spaced apart from one another, to more accurately provide overlay information or alignment information of the first conductive patterns 200. The first overlay key segments 200K may be spaced apart from each other in a direction in which overlay measurement or position measurement is desired.

Referring to FIG. 10, FIG. 11, and FIG. 13, the first pattern array including the first conductive patterns 200 and the first overlay key segments 200K may be positioned to be embedded in the semiconductor substrate 100. Portions of the semiconductor substrate 100 may be recessed to form trenches 200T and 200KT, and the first conductive patterns 200 and the first overlay key segments 200K may be formed to be positioned in the trenches 200T, 200KT.

The first active region 111 and portions of the isolation region 120 are recessed to form first trenches 200T extending across the first active region 111 and the adjacent isolation region 120. The recessed portions of the isolation region 120 are adjacent to the first active region 111. Simultaneously, some portions of the fourth active region 114 in the first overlay key region OLKR1 of the semiconductor substrate 100 may be recessed to form the second trenches 200KT in the fourth active regions 114. The first and second trenches 200T, 200KT are formed at the same time.

The first overlay key segments 200K are formed in the second trenches 200KT while simultaneously forming the first conductive patterns 200 in the first trenches 200T. A first conductive layer is formed to fill the first trenches 200T and the second trenches 200KT. A partial portion of the first conductive layer is removed to separate the first conductive patterns 200 and the first overlay key segments 200K. The portion of the first conductive layer may be removed by an etching back process. The first conductive layer may include a metal layer including, for example, tungsten (W), titanium (Ti), tantalum (Ta), and/or conductive nitrides thereof. The first conductive layer may include a semiconductor layer such as doped-polycrystalline silicon doped with p-type impurities or n-type impurities. The first conductive layer may include a composite layer of a semiconductor layer and a metal layer.

A first dielectric layer 202 fills the trenches 200T and 200KT and covers the first conductive patterns 200 and the first overlay key segments 200K. The first dielectric layer 202 may include an insulating material such as, for example, silicon oxide, silicon nitride, and/or silicon oxynitride. A second dielectric layer, not shown in FIG. 10, may be further formed between the first conductive patterns 200 and the first active region 111 of the semiconductor substrate 100. The second dielectric layer electrically isolates the first conductive patterns 200 from the first active region 111. When the first conductive patterns 200 are formed as cell gate patterns of the cell transistor of the cell devices 109 as shown in FIG. 1, the second dielectric layer is formed as a cell gate dielectric layer. The second dielectric layer may also be formed at an interface between the first overlay key segments 200K and the fourth active region 114. The second dielectric layer may include, for example, silicon oxide.

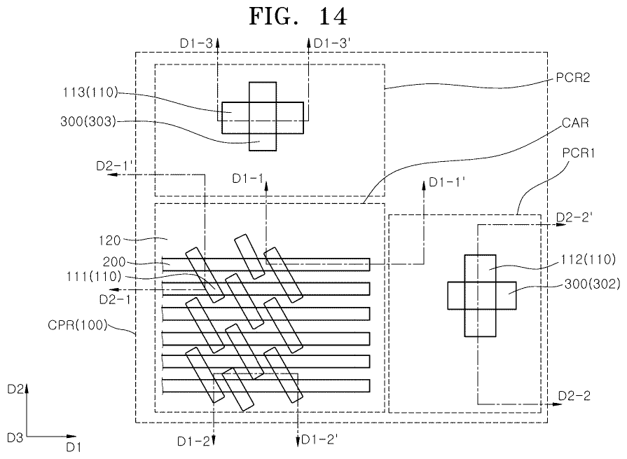

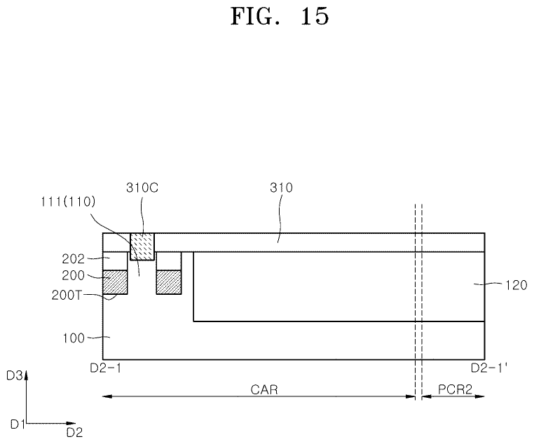

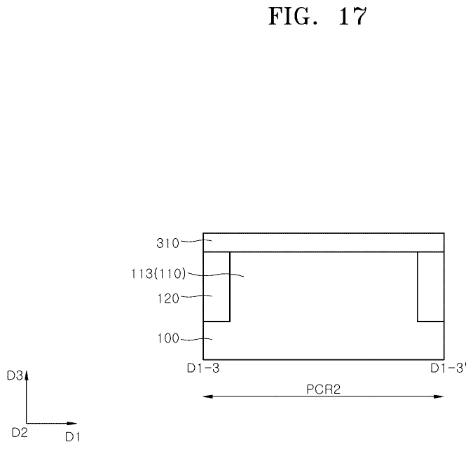

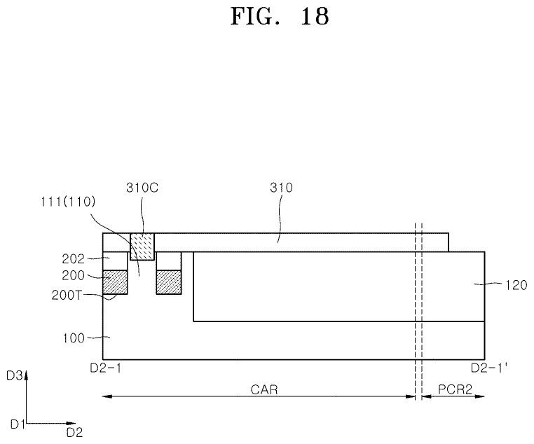

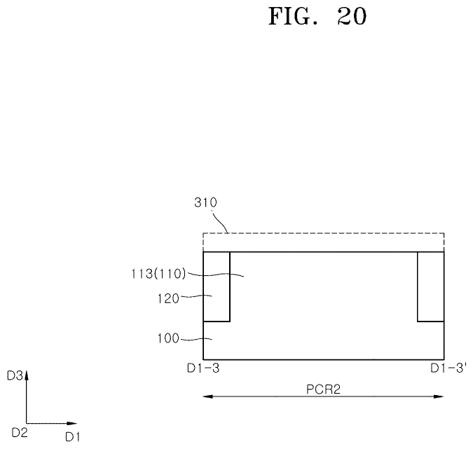

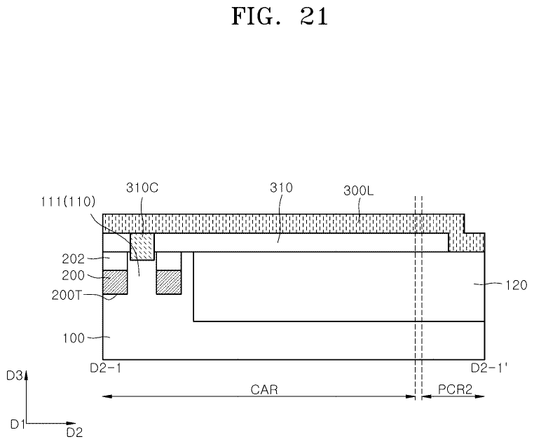

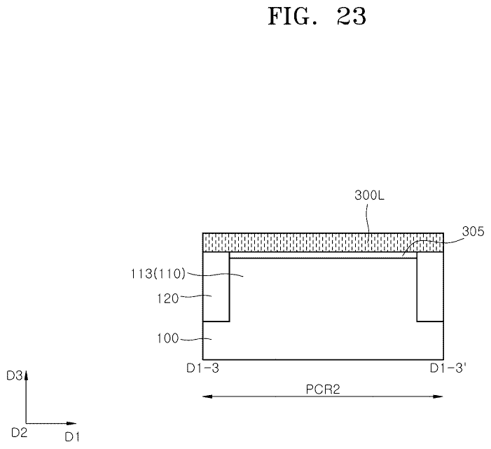

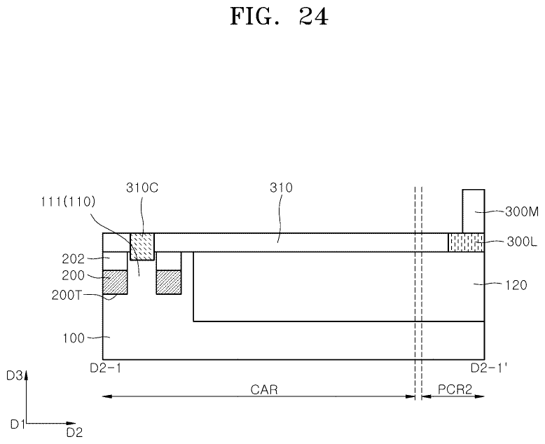

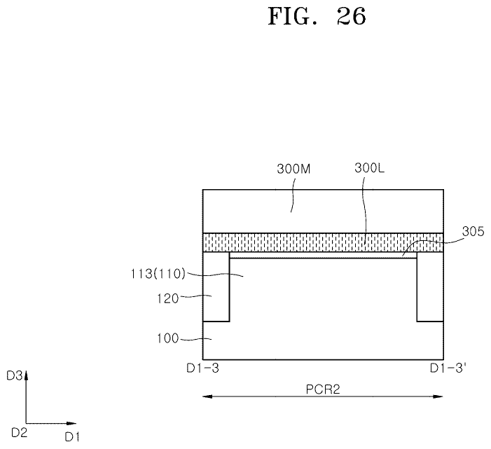

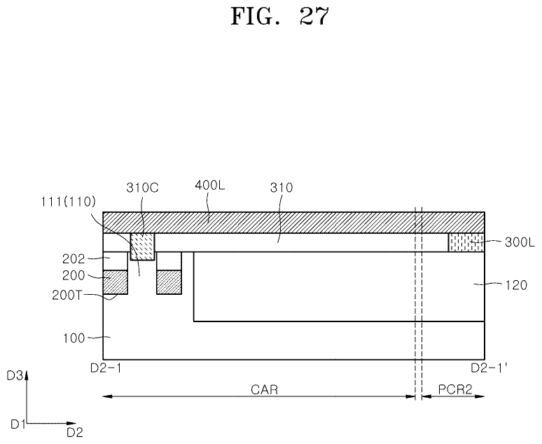

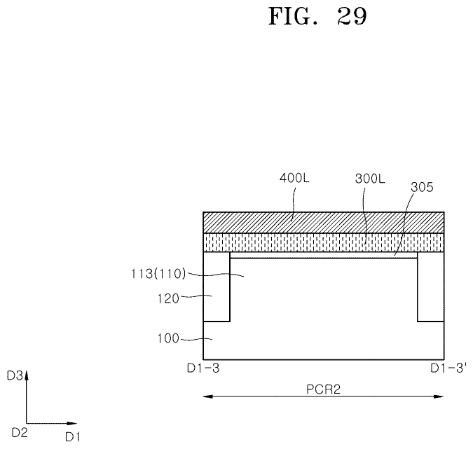

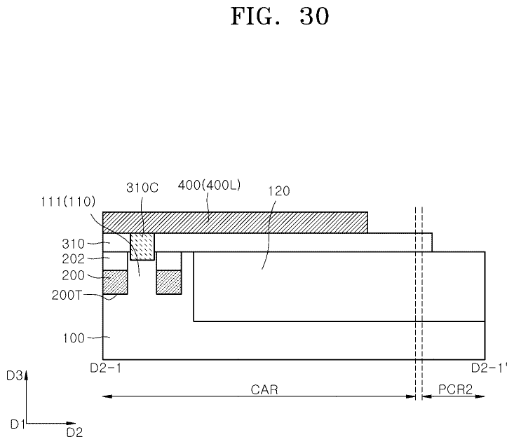

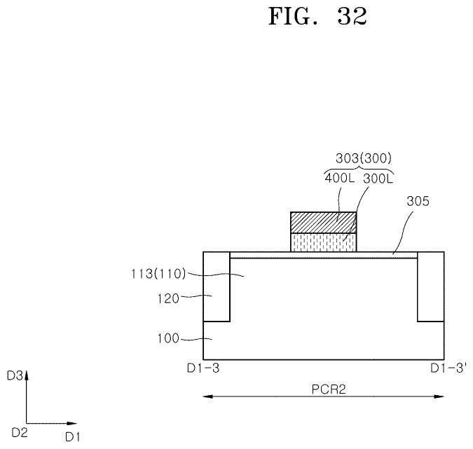

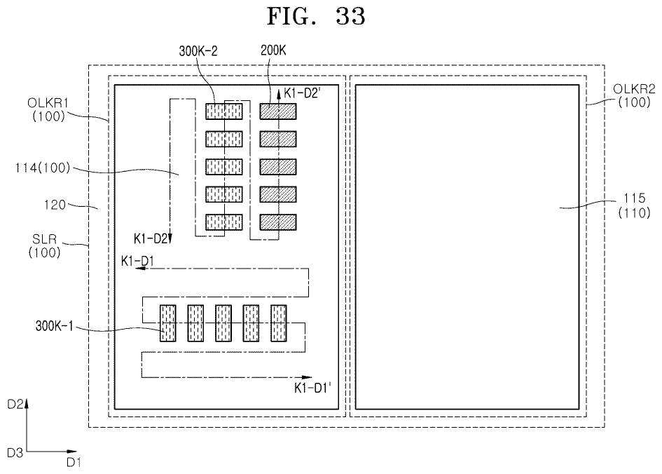

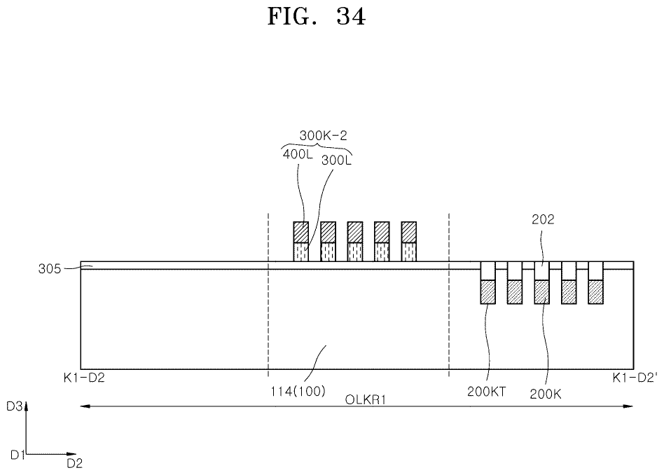

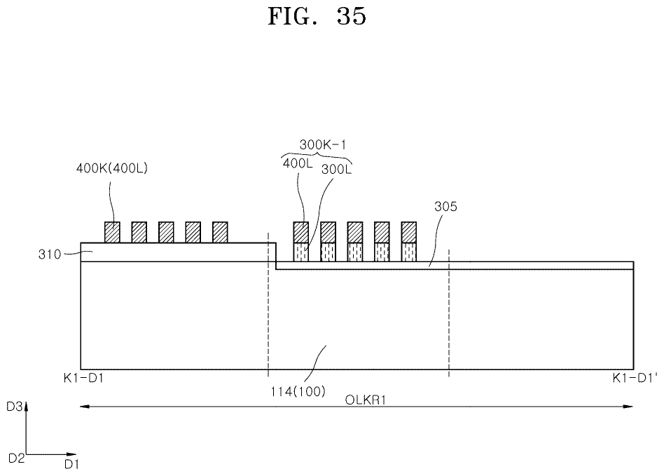

FIG. 14 through FIG. 35 are schematic diagrams illustrating a second pattern array of a semiconductor device according to an embodiment of the present disclosure. FIG. 14 is a schematic plan view illustrating an arrangement of second conductive patterns 300 in the peripheral circuit regions PCR1, and PCR2 of a semiconductor device. FIG. 33 is a schematic plan view illustrating second overlayer key segments 300K-1 and third overlayer key segments 300K-2 of a semiconductor device. The second pattern array includes the second conductive patterns 300 of FIG. 14, and the second and third overlay key segments 300K-1 and 300K-2 of FIG. 33. FIG. 15 through FIG. 17, FIG. 18 through FIG. 20, FIG. 21 through FIG. 23, FIG. 24 through FIG. 26, FIG. 27 through FIG. 29, and FIG. 30 through FIG. 32 are schematic cross-sectional views illustrating process operations for the second conductive patterns 300 of FIG. 14. FIG. 15, FIG. 18, FIG. 21, FIG. 24, FIG. 27, and FIG. 30 are schematic views illustrating cross-sectional shapes along a line from D2-1 to D2-1′ in FIG. 14. FIG. 17, FIG. 20, FIG. 23, FIG. 26, FIG. 29, and FIG. 32 are schematic views illustrating cross-sectional shapes along a line from D1-3 to D1-3′ in FIG. 14. FIG. 34 is a schematic view illustrating cross-sectional shapes along a line from K1-D2 to K1-D2′ in FIG. 33. FIG. 35 is a schematic view illustrating cross-sectional shapes along a line from K1-D1 to K1-D1′ in FIG. 33.

Referring to FIG. 14 and FIG. 33, a second pattern array includes second conductive patterns 300, second overlay key segments 300K-1, and third overlay key segments 300K-2 and is formed over the semiconductor substrate 100. The second conductive patterns 300 of the second pattern array are positioned over peripheral circuit regions PCR1, PCR2 of the semiconductor substrate 100. The second and third overlay key segments 300K-1 and 300K-2 of the second pattern array are positioned over the fourth active region 114 within the first overlay key region OLKR1 of the semiconductor substrate 100.

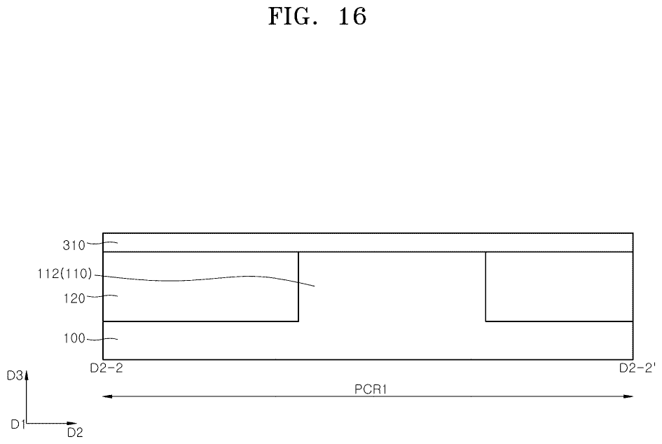

Referring to FIG. 15, FIG. 16, and FIG. 17, for the second pattern array, a third dielectric layer 310 is formed to cover the semiconductor substrate 100. The third dielectric layer 310 may include an insulating material such as, for example, silicon oxide or silicon nitride. A seventh conductive pattern 310C is formed to pass through the third dielectric layer 310. The description of ‘seventh’ indicates an element and is not limited to indicate any order. The seventh conductive pattern 310C is formed as a first connecting contact that substantially vertically connects upper and lower conductive patterns. The seventh conductive pattern 310C may be formed as a connecting element that connects the first active region 111 of the semiconductor substrate 100 and another subsequent conductive pattern. The seventh conductive pattern 310C may be formed as a bit line contact that connects the bit line BL to the cell transistor. The first conductive pattern 200 serves as a cell gate pattern in the cell transistor. The seventh conductive pattern 310C may include a semiconductor layer including polysilicon doped with p-type impurities or n-type impurities.

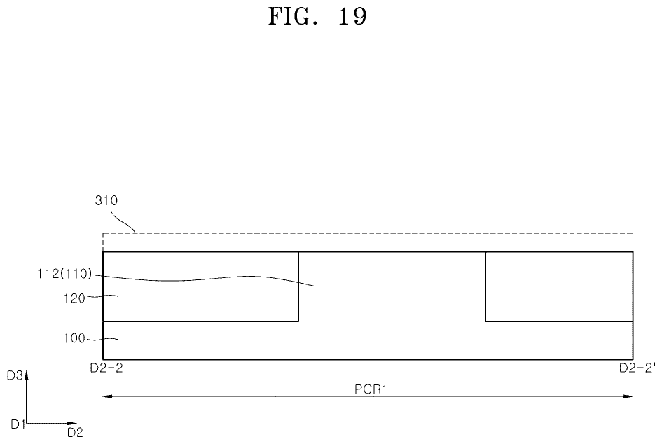

Referring to FIG. 18, FIG. 19, and FIG. 20, a portion of the third dielectric layer 310 is removed to expose the second and third active regions 112, 113 in the peripheral circuit regions PCR1, PCR2. The cell array region CAR of the semiconductor substrate 100 is covered and protected by the remaining third dielectric layer 310. The third dielectric layer 310 may also be formed over the first overlay key region OLKR1 as shown in FIG. 35. The third dielectric layer 310 may remain to cover a portion of the fourth active region 114 in the first overlay key region OLKR1. As a portion of the third dielectric layer 310 is removed, another portion of the fourth active region 114 in the first overlay key region OLKR1 is exposed and revealed from the third dielectric layer 310.

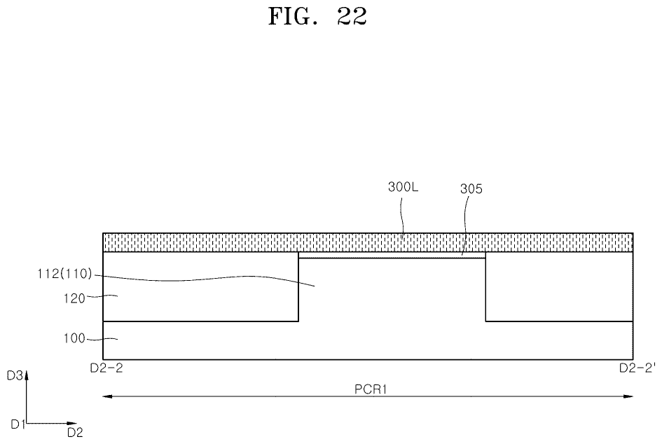

Referring to FIG. 21, FIG. 22, and FIG. 23, a fourth dielectric layer 305 is formed over and covers the second and third active regions 112, 113. The second and third active regions 112, 113 are exposed and revealed by the remaining third dielectric layer 310. The fourth dielectric layer 305 may include, for example, silicon oxide. The fourth dielectric layer 305 covers the exposed fourth active region 114 in the first overlay key region OLKR1 as shown in FIG. 34 and FIG. 35. A second conductive layer 300L is formed over the remaining third dielectric layer 310 and the fourth dielectric layer 305. The second conductive layer 300L covers the remaining third dielectric layer 310 and the fourth dielectric layer 305. The second conductive layer 300L may include a semiconductor layer including polysilicon doped with p-type impurities or n-type impurities.

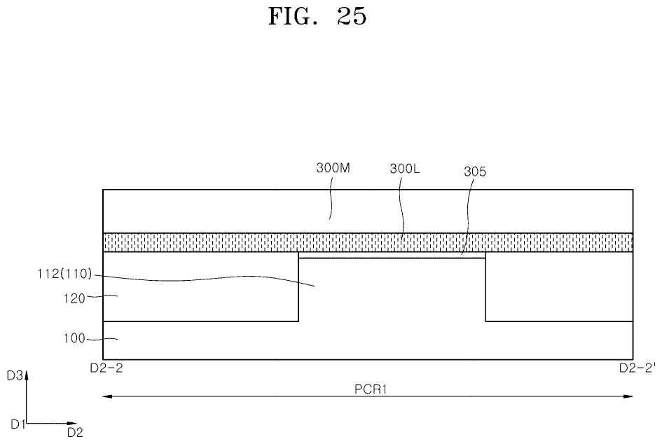

Referring to FIG. 24, FIG. 25, and FIG. 26, a portion of the second conductive layer 300L is removed. The portion of the second conductive layer 300L overlapping the cell array region CAR of the semiconductor substrate 100 is selectively etched out. The second conductive layer 300L is prevented from being positioned over the cell array region CAR of the semiconductor substrate 100. A mask 300M is formed over the second conductive layer (300L). The mask 300M covers the peripheral circuit regions PCR1, PCR2 and the cell array region CAR of the semiconductor substrate 100. Exposed portions of the second conductive layer 300L exposed by the mask 300M are selectively etched and removed. The mask 300M includes a photoresist pattern or a hard mask. As portions of the second conductive layer 300L are removed, a top surface of the seventh conductive pattern 310C is revealed as shown in FIG. 24.

Another portion of the second conductive layer 300L overlapped over the peripheral circuit regions PCR1, PCR2 of the semiconductor substrate 100 is protected by the mask 300M and remains to cover the third dielectric layer 310 and the isolation region 120. In addition, as shown in FIG. 34 and FIG. 35, a portion of the second conductive layer 300L overlapped over the first overlay key region OLKR1 of the semiconductor substrate 100 may be removed, and another portion may remain over the first overlay key region OLKR1.

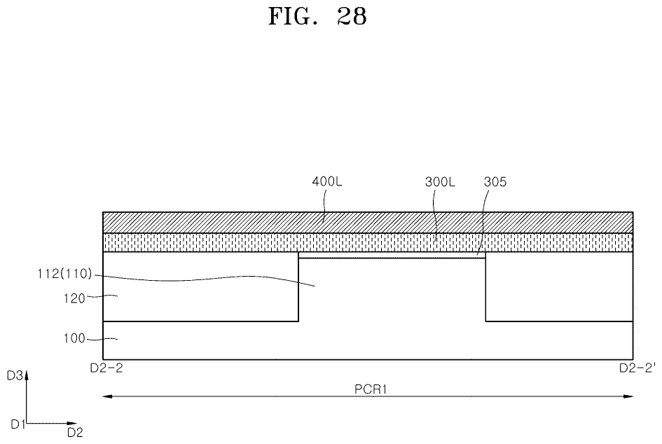

Referring to FIG. 27, FIG. 28, and FIG. 29, a third conductive layer 400L is formed to overlap the remaining second conductive layer 300L. The third conductive layer 400L extends to cover an exposed portion of the third dielectric layer 310. The exposed portion of the third dielectric layer 310 is a portion that is exposed from the remaining second conductive layer 300L. The third conductive layer 400L may be connected to the seventh conductive pattern 310C. The third conductive layer 400L may include a metal layer. The metal layer may include tungsten (W), titanium (Ti), tantalum (Ta), or the like. The metal layer may include conductive metal nitride such as titanium nitride, tantalum nitride, or tungsten nitride. In addition, as shown in FIG. 34 and FIG. 35, the third conductive layer 400L may be simultaneously formed over a portion of the first overlay key region OLKR1 in the semiconductor substrate 100. The third conductive layer 400L extends over a portion of the first overlay key region OLKR1 in the semiconductor substrate 100. The third conductive layer 400L may be formed to overlap the second conductive layer 300L remaining in the first overlay key region OLKR1 or to overlap the third dielectric layer 310 remaining in the first overlay key region OLKR1.

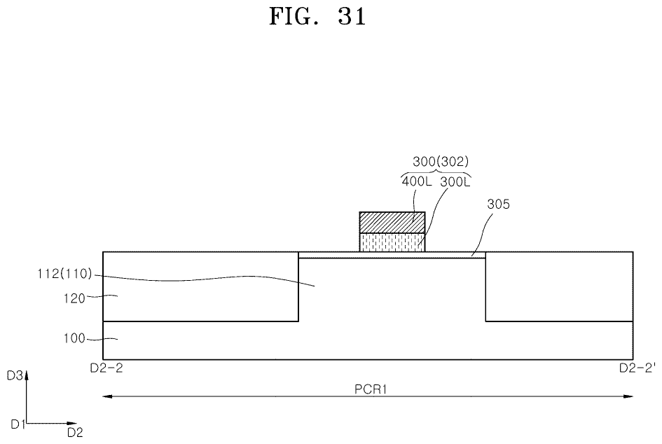

Referring to FIG. 14, FIG. 30, FIG. 31, and FIG. 32, some portions of the third conductive layer 400L and some portions of the second conductive layer 300L are removed to form second conductive patterns 300 over the peripheral circuit regions PCR1, PCR2 of the semiconductor substrate 100. Other portions of the third conductive layer 400L remain without being removed over the cell array region CAR of the semiconductor substrate 100. Other portions of the third conductive layer 400L are not patterned and remain in a state of covering the third dielectric layer 310 over the cell array region CAR of the semiconductor substrate 100.

Referring to FIG. 35, the remaining portion of the third conductive layer 400L over the third dielectric layer 310 does not correspond to the overlay key, and therefore, the remaining portion of the third conductive layer 400L is not illustrated in the plan view of FIG. 33 for convenience. The second overlay key segments 300K-1 and the third overlay key segments 300K-2 may include a double layer of the third conductive layer 400L and the second conductive layer 300L, however, for convenience, the second overlay key segments 300K-1 and the third overlay key segments 300K-2 are indicated with the same hatch as the second conductive layer 300L in the plan view of FIG. 33.

The second pattern array that includes the second conductive patterns 300, the second overlay key segments 300K-1, and the third overlay key segments 300K-2 may be formed by various processes. The process may include forming the third dielectric layer 310, forming the seventh conductive pattern 310C, forming the second conductive layer 300L, and forming the third conductive layer 400L, and removing portions of the layers 310, 300L, 400L, or patterning the layers 310, 300L, 400L.

The second conductive patterns 300, the second overlay key segments 300K-1, and the third overlay key segments 300K-2 may be formed by including a double layer of the second conductive layer 300L and the third conductive layer 400L but are not limited thereto. The second conductive patterns 300, the second overlay key segments 300K-1, and the third overlay key segments 300K-2 may also include a single conductive layer.

The second overlay key segments 300K-1 and the third overlay key segments 300K-2 may be formed at the same time as the second conductive patterns 300 or may be formed simultaneously with the second conductive patterns 300 and thus, they are positioned together in the second pattern array. The second overlay key segments 300K-1, the third overlay key segments 300K-2, and the second conductive patterns 300 may be patterns formed by the same pattern forming process. The process may include a photolithography process, an etching process, and a deposition process.

Referring to FIG. 10, FIG. 11, and FIG. 13, the first conductive patterns 200 and the first overlay key segments 200K of the first pattern array are positioned to be buried in the semiconductor substrate 100. Referring to FIG. 31, FIG. 32, FIG. 34, and FIG. 35, the second overlay key segments 300K-1, the third overlay key segments 300K-2, and the second conductive patterns 300 of the second pattern array are positioned over the semiconductor substrate 100. The second pattern array is positioned over the first pattern array. The second pattern array is positioned farther than the first pattern array from the semiconductor substrate 100. The first pattern array includes preceding patterns formed prior to the second pattern array, and the second pattern array includes subsequent patterns formed after the first pattern array.

Referring to FIG. 14, FIG. 31, and FIG. 32, the second conductive patterns 300 of the second pattern array are positioned over the peripheral circuit regions PCR1, PCR3 of the semiconductor substrate 100. A first sub-conductive pattern 302 of the second conductive patterns 300, is positioned over the first peripheral circuit region PCR1 of the semiconductor substrate 100, and a second sub-conductive pattern 303, which is another part of the second conductive patterns 300, is positioned over the second peripheral circuit region PCR2 of the semiconductor substrate 100. In FIG. 14, FIG. 31, and FIG. 32, the first sub-conductive pattern 302 and the second sub-conductive pattern 303 are depicted as a single unit, but additional first or second-conductive patterns may be further arranged spaced apart from the first sub-conductive pattern 302 or the second sub-conductive pattern 303.

The first sub-conductive pattern 302 is spaced apart in the first direction D1, and the second sub-conductive pattern 303 is spaced apart in the second direction D2, from the cell array region CAR of the semiconductor substrate 100. The first sub-conductive pattern 302 is spaced apart from the first conductive patterns 200 in the first direction D1. The second sub-conductive pattern 303 is spaced apart from the first conductive patterns 200 in the second direction D2.

As the second conductive patterns 300 are arranged at positions spaced apart from each other in the first direction D1 and spaced apart from each other in the second direction D2, overlay or alignment of the second conductive patterns 300 is needed to be measured for both the first direction D1 and the second direction D2. The second overlay key segments 300K-1 may be arranged to be spaced apart in a direction different from the direction in which the third overlay key segments 300K-2 are spaced apart. The second overlay key segments 300K-1 are spaced apart from each other along the first direction D1, and the third overlay key segments 300K-2 are spaced apart from each other along the second direction D2. Accordingly, the second overlay key segments 300K-1 provide displacement or movement of the second conductive patterns 300 in the first direction D1 as overlay information or alignment information. The third overlay key segments 300K-2 provide displacement or movement of the second conductive patterns 300 in the second direction D2 as overlay information or alignment information.

The second conductive patterns 300 may extend across the active regions 112, 113 within the peripheral circuit regions PCR1, PCR3 of the semiconductor substrate 100. The second conductive patterns 300 may be formed as elements constituting peripheral circuits within the peripheral circuit regions PCR1, PCR3 of the semiconductor substrate 100.

Referring to FIG. 14 and FIG. 31, the first sub-conductive pattern 302 is formed as a first peripheral gate pattern constituting a first peripheral transistor within the first peripheral circuit region PCR1. The first sub-conductive pattern 302 may be formed as an element constituting the first sub-word line drivers SWD1 of FIG. 1, within the first peripheral circuit region PCR1.

Referring to FIG. 14 and FIG. 32, the second sub-conductive pattern 303 is formed as a second peripheral gate pattern constituting a second peripheral transistor within the second peripheral circuit region PCR2. The second sub-conductive pattern 303 may be formed as an element constituting the first sense amplifiers SA1 of FIG. 1, within the second peripheral circuit region PCR2.

Referring to FIG. 14, FIG. 31, and FIG. 32, the fourth dielectric layer 305 isolates the second conductive patterns 300 from the active regions 112, 113 of the semiconductor substrate 100. The fourth dielectric layer 305 may be formed as a peripheral gate layer of the first and second peripheral transistors. The fourth dielectric layer 305 may be positioned or extended to isolate the third overlay key segments 300K-2 from the fourth active regions 114 as shown in FIG. 34. The fourth dielectric layer 305 may be positioned to isolate the second overlay key segments 300K-1 from the fourth active regions 114 as shown in FIG. 35.

As illustrated in FIG. 34, the second overlay key segments 300K-1 and the third overlay key segments 300K-2 of the second pattern array are positioned over the semiconductor substrate 100, and the first overlay key segments 200K of the first pattern array are embedded in the semiconductor substrate 100. The second overlay key segments 300K-1 and the third overlay key segments 300K-2 are positioned over the first overlay key segments 200K of the first pattern array. The second overlay key segments 300K-1 and the third overlay key segments 300K-2 may provide overlay information or alignment information of the second pattern array with respect to the first pattern array. The second overlay key segments 300K-1 and the third overlay key segments 300K-2 may provide overlay information or alignment information of the second conductive patterns 300 with respect to the first conductive patterns 200. The second overlay key segments 300K-1 and the third overlay key segments 300K-2 are a second overlay key and a third overlay key that provide alignment information with respect to the second pattern array. The second overlay key segments 300K-1 and the third overlay key segments 300K-2 have a bar shape. The second overlay key segments 300K-1 and the third overlay key segments 300K-2 may be patterns having a larger width, a larger critical line width (CD), and/or larger pitches than the second conductive patterns 300.

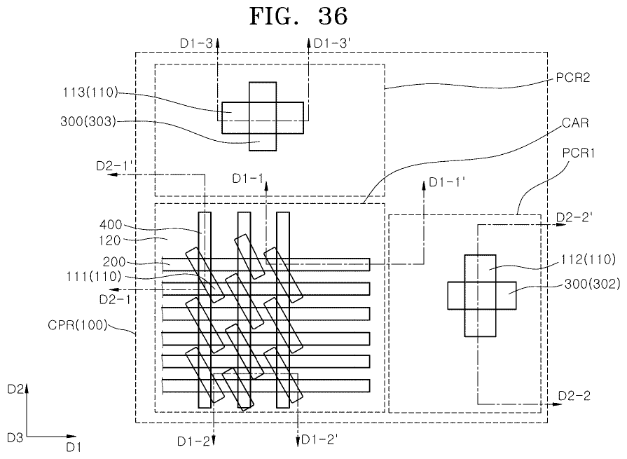

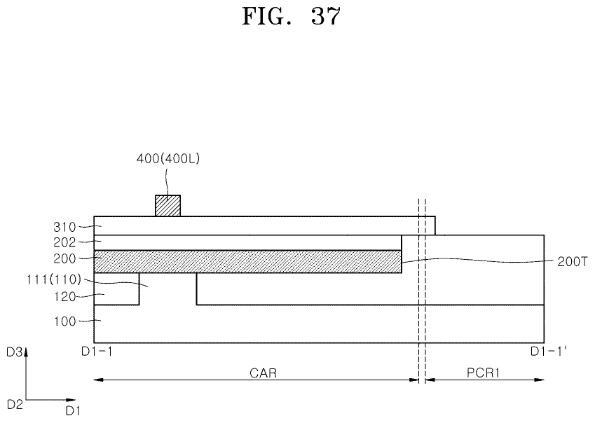

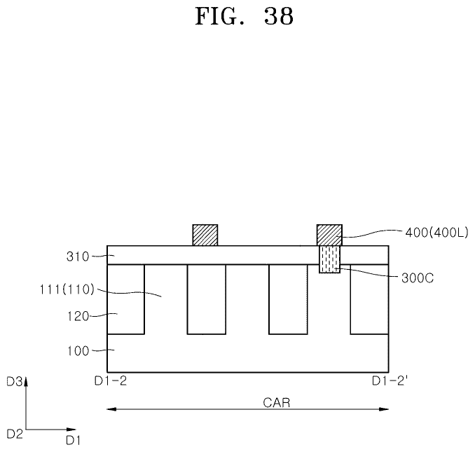

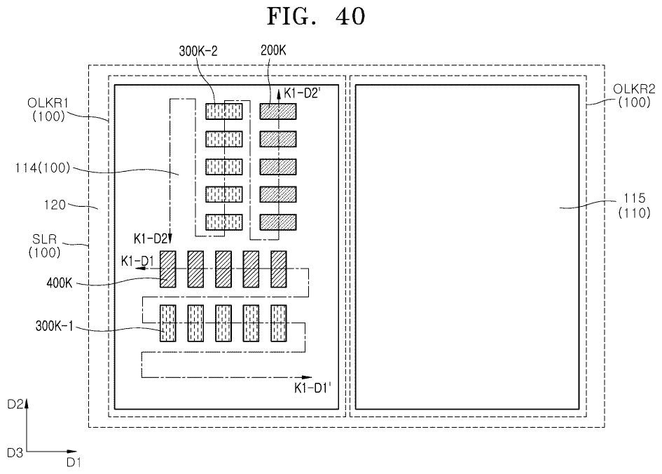

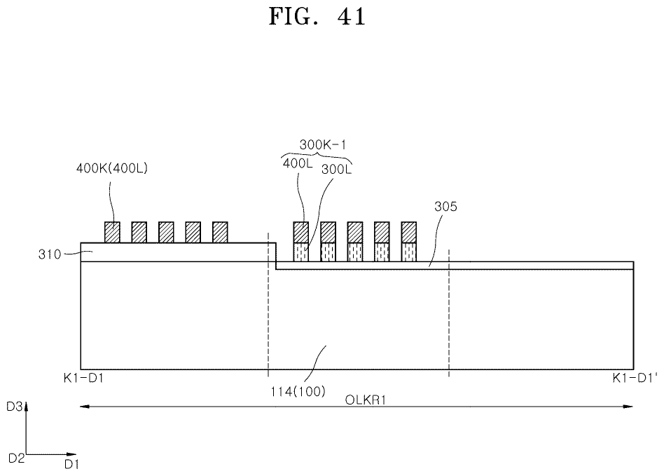

FIG. 36 through FIG. 41 are schematic diagrams illustrating a third pattern array of a semiconductor device according to an embodiment of the present disclosure. FIG. 36 is a schematic plan view illustrating an arrangement of third conductive patterns 400 in a cell array region CAR of a semiconductor device. FIG. 37 is a schematic view illustrating a cross-sectional shape along a line from D1-2 to D1-2′ in FIG. 36. FIG. 38 is a schematic view illustrating a cross-sectional shape along a line from D2-1 to D2-1′ in FIG. 36. FIG. 40 is a schematic plan view illustrating an arrangement of fourth overlay key segments 400K of a semiconductor device. FIG. 41 is a schematic view illustrating a cross-sectional shape along a line from K1-D1 to K1-D1′ in FIG. 40.

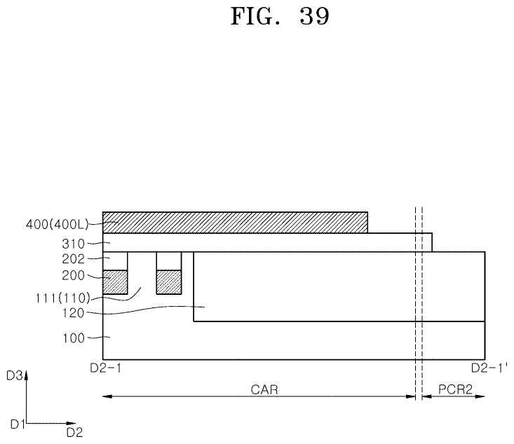

Referring to FIG. 36, FIG. 37, FIG. 38, FIG. 39, FIG. 40, and FIG. 41, a third pattern array is formed over a semiconductor substrate 100. The third pattern array may be positioned over the first pattern array. The third pattern array includes third conductive patterns 400 and fourth overlay key segments 400K. The fourth overlay key segments 400K are formed over the semiconductor substrate 100 simultaneously with the third conductive patterns 400. Forming the fourth overlay key segments 400K at the same time as the third conductive patterns 400, allows the fourth overlay key segments 400K and the third conductive patterns 400 to be positioned together in the third pattern array. The fourth overlay key segments 400K and the third conductive patterns 400 are formed by a pattern forming process including a photolithography process, an etching process, and a deposition process.

Referring to FIG. 36, FIG. 37, FIG. 38, and FIG. 39, the third conductive patterns 400 are formed in line and space shapes. The third conductive patterns 400 may extend in a second direction D2 over the semiconductor substrate 100 and may be spaced apart from each other along the first direction D1. The third conductive patterns 400 may be line patterns that extend parallel to each other in the second direction D2. The third conductive patterns 400 are positioned within the cell array region CAR over the semiconductor substrate 100.

The third conductive patterns 400 cross over the first conductive patterns 200. The third conductive patterns 400 are isolated or spaced apart from the semiconductor substrate 100 by the third dielectric layer 310 in the third direction D3. The third conductive patterns 400 may be formed as bit lines of the cell devices 109 of FIG. 1. One of the third conductive patterns 400 may be connected to a cell transistor constituting the cell devices 109 of FIG. 1 by the seventh conductive pattern 300C.

Referring to FIG. 36, FIG. 40, and FIG. 41, the fourth overlay key segments 400K are formed over the semiconductor substrate 100 to be disposed over the first overlay key region OLKR1. As the third conductive patterns 400 are spaced apart from each other along the first direction D1, overlay or alignment of the third conductive patterns 400 is measured along the first direction D1. The fourth overlay key segments 400K are formed spaced apart from each other along the first direction D1. The first direction D1 is the same as the direction in which the third conductive patterns 400 are spaced apart. The fourth overlay key segments 400K have a bar shape. The fourth overlay key segments 400K may be patterns having a larger width, a larger critical line width (CD), or/and larger pitches than the third conductive patterns 400. The fourth overlay key segments 400K serve as a fourth overlay key that provide overlay information of the third pattern array.

As the third conductive patterns 400 and the fourth overlay key segments 400K constituting the third pattern array are formed at the same time, when the third conductive pattern 400 is patterned into patterns moved or displaced from the position intended in the design, the fourth overlay Key segments 400K are also patterned into patterns shifted or displaced from the location intended in the design. Overlay information or alignment information between the third conductive patterns 400 and the second conductive patterns 300 in FIG. 36, which are the preceding patterns, is measured by measuring the positions of the fourth overlay key segments 400K with respect to the second overlay key segment 300K-1, which is the preceding patterns formed above. Overlay information or alignment information between the third conductive patterns 400 and the second conductive patterns 300 may be measured by comparing the planar shapes (or images) of the second overlay Key segments 300K-1 and the fourth overlay Key segment 400K. Overlay information or alignment information between the third conductive patterns 400 and subsequent patterns may be measured by comparing the positions of the fourth overlay key segments 400K and subsequent overlay key segments to be subsequently formed.

Referring to FIG. 37, FIG. 38, FIG. 39, and FIG. 41, the third pattern array including the third conductive patterns 400 and the fourth overlay key segments 400K is formed to be located over the third dielectric layer 310 in the semiconductor substrate 100. As illustrated in FIG. 30, FIG. 31, FIG. 34, and FIG. 35, the third conductive layer 400L remains over the third dielectric layer 310 while the second conductive patterns 300 of FIG. 31 and the second and third overlay key segments 300K-1 and 300K-2 are patterned. The third conductive layer 400L is maintained in a state of covering the third dielectric layer 310 over the cell array region CAR, or in a state of coating the third dielectric layer 210 over the first overlay key region OLKR1. By patterning the third conductive layer 400L, the third pattern array is formed to include the third conductive patterns 400 and the fourth overlay key segments 400K. The third pattern array is formed by selectively etching and removing some portions of the third conductive layer 400L.

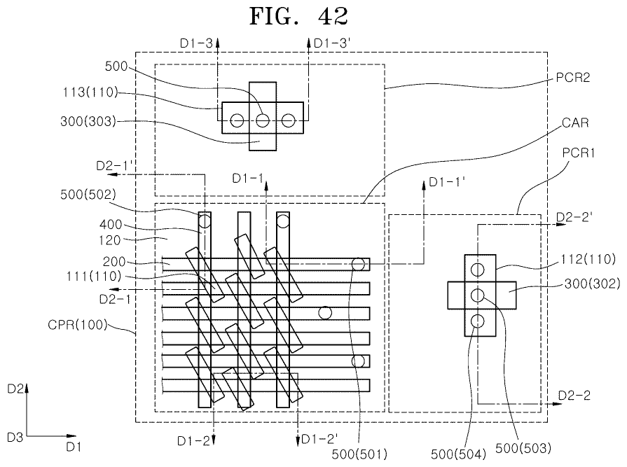

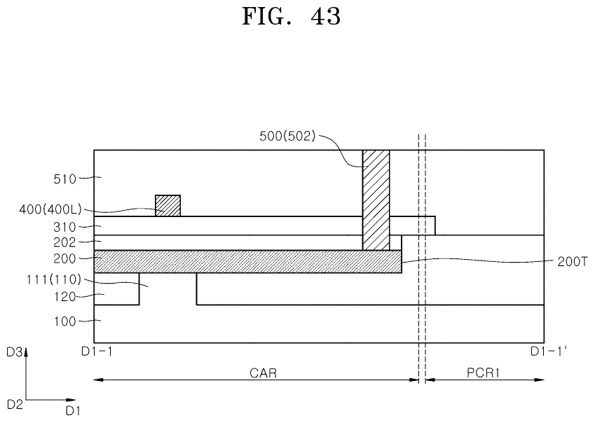

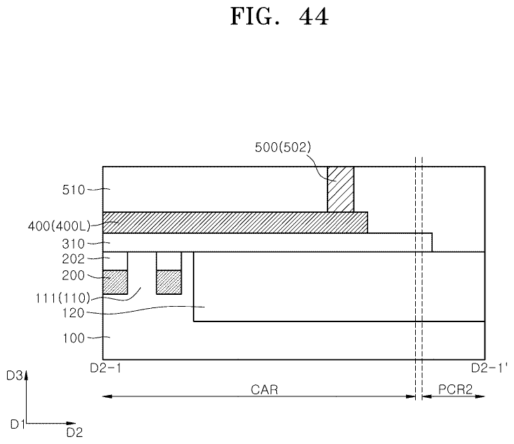

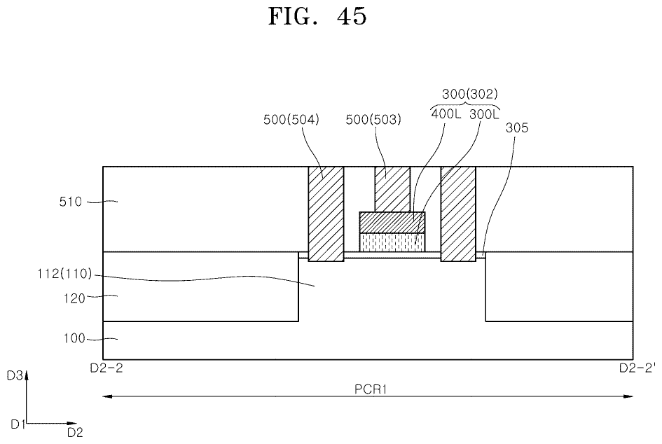

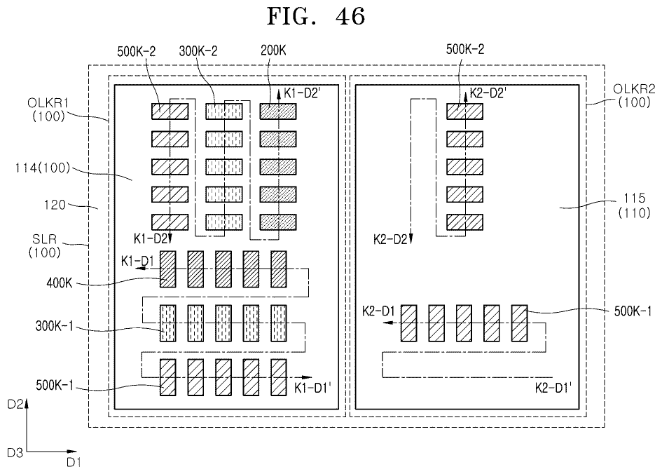

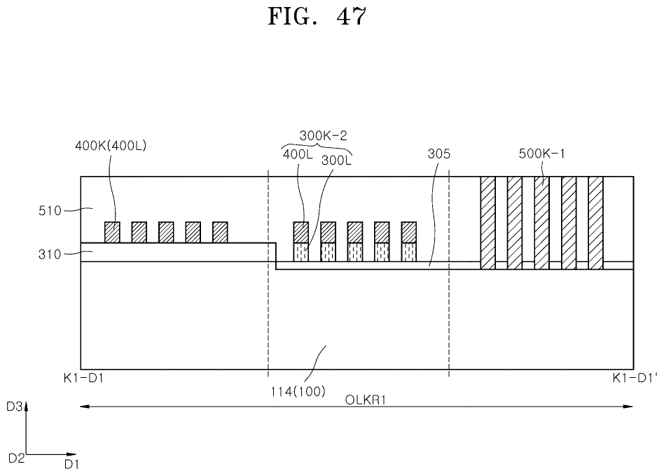

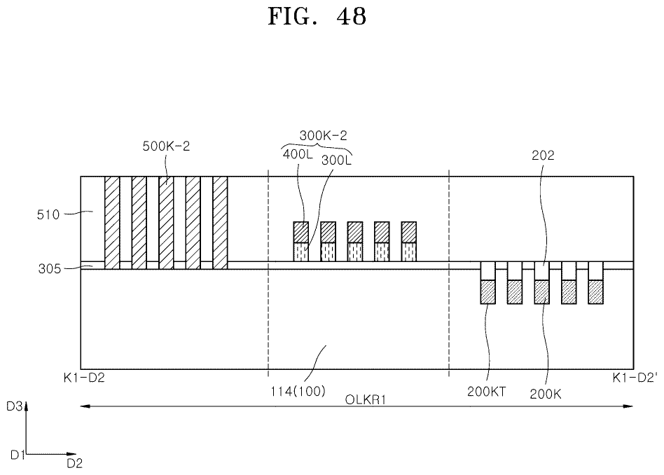

FIG. 42 through 48 are schematic diagrams illustrating a fourth pattern array of a semiconductor device according to an embodiment of the present disclosure. FIG. 42 is a schematic plan view illustrating an arrangement of fourth conductive patterns 500 over a cell array region CAR and peripheral circuit regions PCR1, PCR2 of a semiconductor device. FIG. 43 is a schematic view illustrating a cross-sectional shape along a line from D1-1 to D1-1′ in FIG. 42. FIG. 44 is a schematic view illustrating a cross-sectional shape along a line from D2-1 to D2-1′ in FIG. 42. FIG. 45 is a schematic view illustrating a cross-sectional shape along a line from D2-2 to D2-2′ in FIG. 42. FIG. 46 is a schematic plan view illustrating an arrangement of fifth overlay key segments 500K-1 and sixth overlay key segments 500K-2 of a semiconductor device. FIG. 47 is a schematic view illustrating a cross-sectional shape along a line from K1-D1 to K1-D1′ in FIG. 46. FIG. 48 is a schematic view illustrating a cross-sectional shape along a line from K1-D2 to K1-D2′ in FIG. 46.

Referring to FIG. 42, FIG. 43, FIG. 44, FIG. 45, FIG. 46, FIG. 47, and FIG. 48, a fourth pattern array is formed over a semiconductor substrate 100. The fourth pattern array may be positioned over the first, second and third pattern arrays. The fourth pattern array includes fourth conductive patterns 500 of FIG. 42 and fifth overlay key segments 500K-1 and sixth overlay key segments 500K-2 of FIG. 46. The fifth overlay key segments 500K-1 and the sixth overlay key segments 500K-2 are formed over the semiconductor substrate 100 simultaneously with the fourth conductive patterns 500. As the fifth overlay key segments 500K-1 and the sixth overlay key segments 500K-2 are formed at same time as the fourth conductive patterns 500, the fourth conductive patterns 500, the fifth overlay key segments 500K-1 and the sixth overlay key segments 500K-2 are positioned together in the fourth pattern array. The fifth overlay key segments 500K-1, the sixth overlay key segments 500K-2, and the fourth conductive patterns 500 are formed by a pattern forming process. The pattern forming process includes a photolithography process, an etching process, a deposition process, a process of separating the deposited layer into individual patterns, and the like.

Referring to FIG. 42, FIG. 43, FIG. 44, and FIG. 45, the fourth conductive patterns 500 are formed as connecting elements that may be connected to the first, second, and third conductive patterns 200, 300, 400, which are preceding patterns, and/or to portions of the semiconductor substrate 100. The fourth conductive patterns 500 may be second connecting contacts that may be connected to the first, second, and third conductive patterns 200, 300, 400 and/or to second and third active regions 112, 113 of the semiconductor substrate 100, respectively. As the first conductive patterns 200 are formed as the word lines WL of FIG. 1, the second conductive patterns 300 are formed as the peripheral gate patterns of the peripheral transistors, and the third conductive patterns 300 are configured as the bit lines BL of FIG. 1, the fourth conductive patterns 500 include the second connection contacts that are respectively connected to the word lines WL, the bit lines BL, and the peripheral transistors.

The fourth conductive patterns 500 are spaced apart from each other in the first direction D1 and the second direction D2 over the semiconductor substrate 100. The fourth conductive patterns 500 include metal material such as tungsten W.

Referring to FIG. 46, the fifth overlay key segments 500K-1 and the sixth overlay key segments 500K-2 may be arranged within the first overlay key region OLKR1 over the semiconductor substrate 100. The fifth overlay key segments 500K-1 are designed to be arranged parallel to the second overlay key segments 300K-1 and the fourth overlay key segments 400K. The fifth overlay key segments 500K-1, the second overlay key segments 300K-1, and the fourth overlay key segments 400K may be arranged sequentially along the second direction D2. The fifth overlay key segments 500K-1 may be arranged spaced apart from each other along the first direction D1.

The sixth overlay key segments 500K-2 may be designed to be arranged in parallel with the third overlay key segments 300K-2 and the first overlay key segments 200K. The sixth overlay key segments 500K-2, the third overlay key segments 300K-2, and the first overlay key segments 200K may be arranged sequentially along the first direction D1. The sixth overlay key segments 500K-2 may be arranged to be spaced apart from each other along the second direction D2. Additional fifth overlay key segments 500K-1 and additional sixth overlay key segments 500K-2 may be further formed to be arranged within the second overlay key region OLKR2 over the semiconductor substrate 100.

Referring to FIG. 42 and FIG. 46, as the fourth conductive patterns 500 may be arranged while being spaced apart from each other in the first and second directions D1, D2 over the semiconductor substrate 100, the degree of overlay or alignment of the fourth conductive patterns 500 may be measured for both the first and second directions D1, D2. The fifth overlay key segments 500K-1 are formed to be spaced apart from each other along the first direction D1 which is the same as the direction in which some of the fourth conductive patterns 500 are spaced apart from each other. The sixth overlay key segments 500K-2 are formed to be spaced apart from each other along the second direction D2 which is the same as the direction in which the other of the fourth conductive patterns 500 are spaced apart from each other.

The fifth and sixth overlay key segments 500K-1, 500K-2 have a bar shape. The fifth and sixth overlay key segments 500K-1, 500K-2 may be patterns having a larger width, a larger critical line width (CD), and/or larger pitches than the fourth conductive patterns 500. The fifth and sixth overlay key segments 500K-1, 500K-2 are fifth and sixth overlay keys that provide overlay information of the fourth pattern array. As the fourth conductive patterns 500 and the fifth and sixth overlay key segments 500K-1, 500K-2 constituting the fourth pattern array are formed at the same time, when the fourth conductive patterns 500 are patterned as patterns moved or displaced from the position intended in design, the fifth and sixth overlay key segments 500K-1, 500K-2 are patterned as patterns moved or displaced from the position intended in design.

By measuring the position of the fifth overlay key segments 500K-1 with respect to the second overlay key segments 300K-1 and the fourth overlay key segments 400K, which are previously formed preceding patterns, it is possible to measure overlay information or alignment information along the first direction D1 between the fourth conductive patterns 500 and the second conductive patterns 300, which are preceding patterns, as well as other overlay information or other alignment information along the first direction D1 between the fourth conductive patterns 500 and the third conductive patterns 400, which are other preceding patterns.

By comparing planar shapes or images of the fifth overlay key segments 500K-1 with respect to the second overlay key segments 300K-1 and the fourth overlay key segments 400K, it is possible to measure overlay information or alignment information along the first direction D1 between the fourth conductive patterns 500 and the second conductive patterns 300 as well as other overlay information or other alignment information along the first direction D1 between the fourth conductive patterns 500 and the third conductive patterns 400.

By measuring the position of the sixth overlay key segments 500K-2 with respect to the third overlay key segments 300K-2 and the first overlay key segments 200K, which are previously formed preceding patterns, it is possible to measure overlay information or alignment information along the second direction D2 between the fourth conductive patterns 500 and the second conductive patterns 300, which are preceding patterns, as well as other overlay information or alignment information along the second direction D2 between the fourth conductive patterns 500 and the first conductive patterns 200, which are other preceding patterns.

By comparing planar shapes or images of the sixth overlay key segments 500K-2 with respect to the third overlay key segments 300K-2 and the first overlay key segments 200K, it is possible to measure overlay information or alignment information along the first direction D2 between the fourth conductive patterns 500 and the second conductive patterns 300, as well as other overlay information or alignment information along the second direction D2 between the fourth conductive patterns 500 and the first conductive patterns 200.

The first, second, third, fourth, fifth, and sixth overlay key segments 200K, 300K-1, 300K-2, 400K, 500K-1, 500K-2 provide alignment information of the fourth pattern array with respect to the first, second, and third pattern arrays. Through overlay measurement using the first, second, third, fourth, fifth, and sixth overlay key segments 200K, 300K-1, 300K-2, 400K, 500K-1, 500K-2, overlay information or alignment information of the fourth conductive patterns 500 with respect to the first, second, and third conductive patterns 200, 300, 400 are obtained. This overlay information or alignment information helps prevent misalignment of the fourth conductive patterns 500 with respect to the first, second, and third conductive patterns 200, 300, 400.

Referring to FIG. 43, FIG. 44, FIG. 45, FIG. 47, and FIG. 48, the fourth conductive patterns 500, the fifth overlay key segments 500K-1, and sixth overlay key segments 500K-2 of the fourth pattern array are formed over the semiconductor substrate 100. A fifth dielectric layer 510 covers the third conductive patterns 400 and the fourth overlay key segments 400K of the third pattern array over the semiconductor substrate 100. The fifth dielectric layer 510 may include, for example, silicon oxide or silicon nitride. Through holes penetrating the fifth dielectric layer 510 may be further formed, the through holes may be filled with a conductive layer, and a portion of the conductive layer may be removed to separate the fourth conductive patterns 500 from the conductive layer by the through holes.

Referring to FIG. 42 and FIG. 43, third sub-conductive patterns 501 of the fourth conductive patterns 500 are formed to pass through the fifth dielectric layer 510, the third dielectric layer 310, and the first dielectric layer 202 and connect to the first conductive patterns 200 embedded in the semiconductor substrate 100. in FIG. 42, some of the first conductive pattern 200 are illustrated not to overlap with the third sub-conductive patterns 501, however they may be connected to additional third sub-conductive patterns on the opposite side that are not illustrated. As the third sub-conductive patterns 501 are alternately connected to the first conductive patterns 200 one by one, a spacing between the third sub-conductive patterns 501 may be secured longer, and thus, a defect in which the third sub-conductive patterns 501 are undesirably electrically connected to each other may be suppressed.

Referring to FIG. 42 and FIG. 44, fourth sub-conductive patterns 502 of the fourth conductive patterns 500 are formed to pass through the fifth dielectric layer 510 and be connected to the third conductive patterns 400 over the semiconductor substrate 100. In FIG. 42, one of the third conductive patterns 400 is illustrated not to overlap with the fourth sub-conductive pattern 502, however it may be connected to an additional fourth sub-conductive pattern on the opposite side that is not illustrated. As the fourth sub-conductive patterns 502 are alternately connected to the third conductive patterns 400 one by one, a spacing between the fourth sub-conductive patterns 502 can be secured longer.

Referring to FIG. 42 and FIG. 45, fifth sub-conductive patterns 503 of the fourth conductive patterns 500 are formed to pass through the fifth dielectric layer 510 and be connected to the second conductive patterns 300 over the semiconductor substrate 100. Sixth sub-conductive patterns 504 of the fourth conductive patterns 500 are formed to pass through the fifth dielectric layer 510 and the fourth dielectric layer 305 and be connected to the second active region 112 of the active regions 110 in the semiconductor substrate 100. The fourth conductive patterns 500 includes the third sub-conductive patterns 501, the fourth sub-conductive patterns 502, the fifth sub-conductive patterns 503, and the sixth sub-conductive patterns 504.

Referring to FIG. 42, FIG. 43, FIG. 44, and FIG. 45, targets or objects to which the fourth conductive patterns 500 are connected are the first conductive patterns 200, the third conductive patterns 400, the second conductive patterns 300, and the active regions 110 of the semiconductor substrate 100. Depths or thicknesses of the fourth conductive patterns 500 extending in the third direction D3 vary depending on the targets to which the fourth conductive patterns 500 are connected.

Referring to FIG. 46, FIG. 47, and FIG. 48, the fifth overlay key segments 500K-1 and the sixth overlay key segments 500K-2 are formed in the first overlay key region OLKR1 of the semiconductor substrate 100 simultaneously with the fourth conductive patterns 500 of FIG. 42, FIG. 43, FIG. 44, and FIG. 45. As the fifth overlay key segments 500K-1 and the sixth overlay key segments 500K-2 are formed at the same time as the fourth conductive patterns 500, the fifth overlay key segments 500K-1 and the sixth overlay key segments 500K-2 may have a depth or thickness extending in the third direction D3 that is substantially the same as one of the fourth conductive patterns 500. The fifth overlay key segments 500K-1 and the sixth overlay key segments 500K-2 may have a depth or thickness extending in the third direction D3 substantially the same as the sixth sub-conductive patterns 504 of FIG. 45 but are not limited thereto.

The fifth overlay key segments 500K-1 and the sixth overlay key segments 500K-2 are formed to be positioned next to the second overlay key segments 300K-1 and the third overlay key segments 300K-2 in the first overlay key region OLKR1, respectively. Additional fifth overlay key segments 500K-1 and additional sixth overlay key segments 500K-2 may be further disposed over the second overlay key region OLKR2 for comparison with other subsequent overlay key segments.

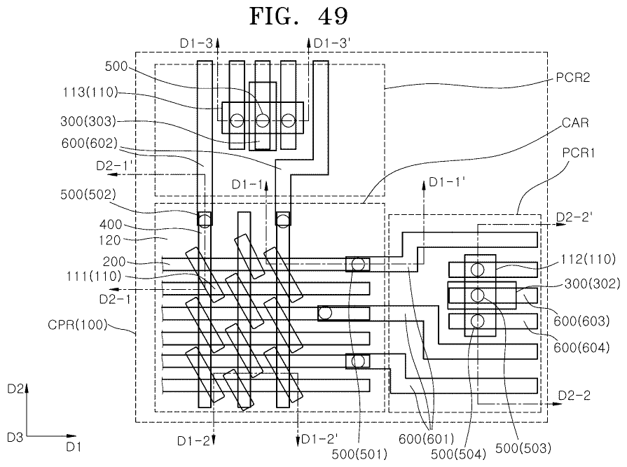

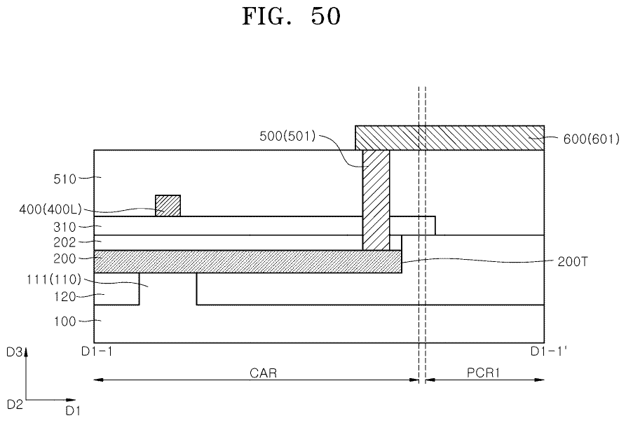

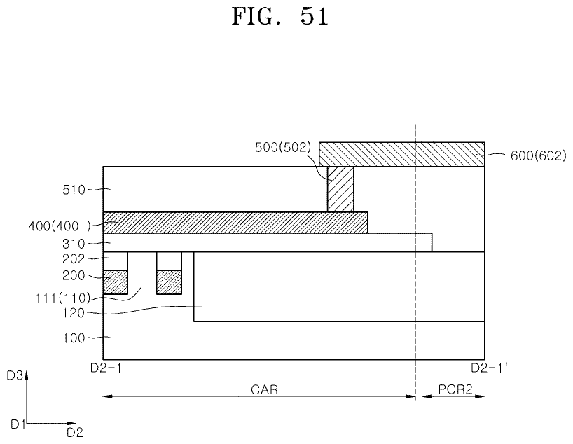

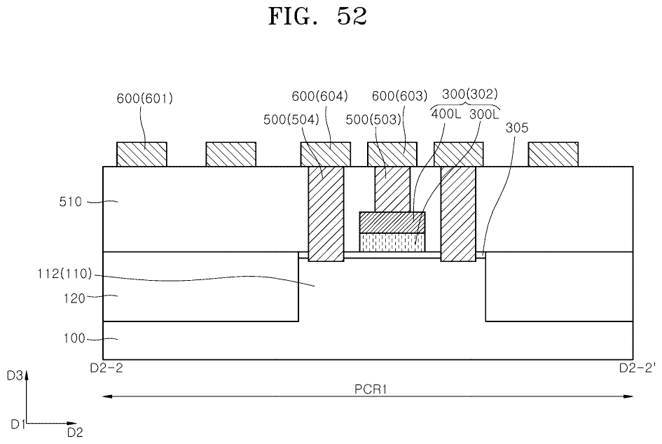

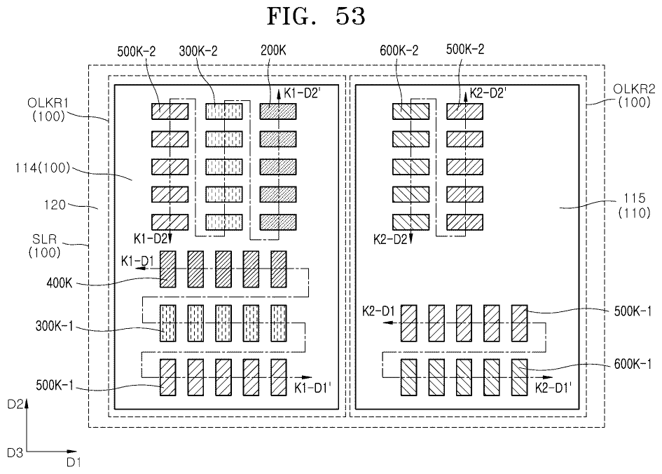

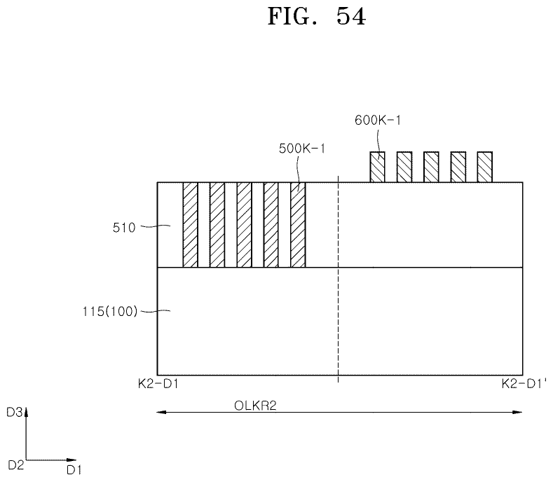

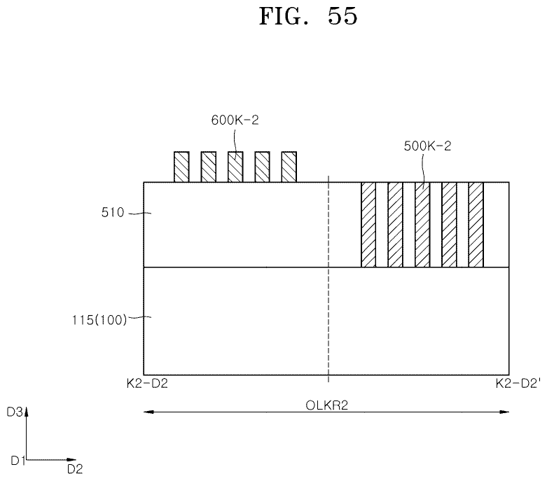

FIG. 49 through 55 are schematic diagrams illustrating a fifth pattern array of a semiconductor device according to an embodiment of the present disclosure. FIG. 49 is a schematic plan view illustrating an arrangement of fifth conductive patterns 600 in a chip region CPR of a semiconductor device. FIG. 50 is a schematic view illustrating a cross-sectional shape along a line from D1-1 to D1-1′ in FIG. 49. FIG. 51 is a schematic view illustrating a cross-sectional shape along a line from D2-1 to D2-1′ in FIG. 49. FIG. 52 is a schematic view illustrating a cross-sectional shape along a line from D2-2 to D2-2′ in FIG. 49. FIG. 53 is a schematic plan view illustrating an arrangement of seventh overlay key segments 600K-1 and eighth overlay key segments 600K-2 of a semiconductor device. FIG. 54 is a schematic view illustrating a cross-sectional shape along a line from K2-D1 to K2-D1′ in FIG. 53. FIG. 55 is a schematic view illustrating a cross-sectional shape along a line from K2-D2 to K2-D2′ in FIG. 53.

Referring to FIG. 49, FIG. 50, FIG. 51, FIG. 52, FIG. 53, FIG. 54, and FIG. 55, a fifth pattern array is formed over the fifth dielectric layer 510 of the semiconductor substrate 100. The fifth pattern array includes the fifth conductive patterns 600 of FIG. 49, and the seventh overlay key segments 600K-1 and the eighth overlay key segments 600K-2 of FIG. 53. The seventh overlay key segments 600K-1 and the eighth overlay key segments 600K-2 are formed simultaneously with the fifth conductive patterns 600. As the seventh overlay key segments 600K-1 and the eighth overlay key segments 600K-2 are formed at the same time as the fifth conductive patterns 600, the seventh overlay key segments 600K-1, the eighth overlay key segments 600K-2, and the fifth conductive patterns 600 are positioned together in the fifth pattern array. The seventh overlay key segments 600K-1, the eighth overlay key segments 600K-2, and the fifth conductive patterns 600 may be formed by a pattern forming process. The pattern forming process includes a photolithography process, an etching process, a deposition process, etc.

Referring to FIG. 49, FIG. 50, FIG. 51, and FIG. 52, the fifth conductive patterns 600 may be formed as wirings that are respectively connected to the fourth conductive patterns 500, which are the preceding patterns. The fifth conductive patterns 600 are electrically connected to the first, second, and third conductive patterns 200, 300, 400, respectively, by being connected to the fourth conductive patterns 500, and/or may be electrically connected to the second and third active regions 112, 113 of the semiconductor substrate 100, respectively. The fourth conductive patterns 500 are formed as connecting contacts that connect the fifth conductive patterns 600 to the first, second, and third conductive patterns 200, 300, 400 and to some portions of the semiconductor substrate 100.

The seventh sub-conductive patterns 601 of the fifth conductive patterns 600 may extend in the first direction D1 over the semiconductor substrate 100 and may be spaced apart from each other in the second direction D2. The seventh sub-conductive patterns 601 may be connected to the third sub-conductive patterns 501 of the fourth conductive patterns 500. The seventh sub-conductive patterns 601 may be connected to the first conductive patterns 200 through the third sub-conductive patterns 501. The seventh sub-conductive patterns 601 may be wirings connected to the word lines WL of FIG. 1.

The eighth sub-conductive patterns 602 of the fifth conductive patterns 600 are spaced apart from each other in the first direction D1 while extending in the second direction D2 over the semiconductor substrate 100. The eighth sub-conductive patterns 602 may be connected to the fourth sub-conductive patterns 502 of the fourth conductive patterns 500. The eighth sub-conductive patterns 602 may be connected to the third conductive patterns 400 through the fourth sub-conductive patterns 502. The eighth sub-conductive patterns 602 may be wirings connected to the bit lines BL of FIG. 1.

The ninth sub-conductive pattern 603 of the fifth conductive patterns 600 may be connected to the fifth sub-conductive pattern 503 of the fourth conductive patterns 500. The ninth sub-conductive pattern 603 may be connected to the first sub-conductive pattern 302 of the second conductive patterns 300 through the fifth sub-conductive pattern 503. The ninth sub-conductive pattern 603 may be a wiring connected to the first sub-conductive pattern 302. The first sub-conductive pattern 302 may be a peripheral gate pattern of a peripheral transistor.

The tenth sub-conductive patterns 604 of the fifth conductive patterns 600 may be respectively connected to the sixth sub-conductive patterns 504 of the fourth conductive patterns 500. The tenth sub-conductive patterns 604 may be connected to the second active region 112 of the active regions 110 of the semiconductor substrate 100 through the sixth sub-conductive patterns 504. The ninth and tenth sub-conductive patterns 603, 604 may be wirings connected to a peripheral transistor including the second active region 112 and the first sub-conductive pattern 302.

The fifth conductive patterns 600 include the seventh sub-conductive patterns 601, the eighth sub-conductive patterns 602, the ninth sub-conductive pattern 603, and the tenth sub-conductive patterns 604. The fifth conductive patterns 600 may include a metal layer such as, for example, tungsten (W) layer. The fifth conductive patterns 600 may further include a barrier layer including, for example, titanium (Ti), tungsten nitride (WN), or tungsten silicon nitride (WSiN).

Referring to FIG. 53, the seventh overlay key segments 600K-1 and the eighth overlay key segments 600K-2 are formed to be arranged within the second overlay key region OLKR2 over the semiconductor substrate 100. The seventh overlay key segments 600K-1 may be arranged parallel to the fifth overlay key segments 500K-1. The seventh overlay key segments 600K-1 and the fifth overlay key segments 500K-1 may be arranged sequentially along the second direction D2 over the second overlay key region OLKR2. Additional seventh overlay key segments 600K-1 may be disposed over the first overlay key region OLKR1 and positioned next to the fifth overlay key segments 500K-1. The seventh overlay key segments 600K-1 are spaced apart from each other along the first direction D1.

The eighth overlay key segments 600K-2 may be arranged parallel to the sixth overlay key segments 500K-2. The eighth overlay key segments 600K-2 and the sixth overlay key segments 500K-2 may be arranged sequentially along the first direction D1. The eighth overlay key segments 600K-2 may be arranged next to the sixth overlay key segments 500K-2 within the second overlay key region OLKR2. Additional eighth overlay key segments 600K-2 may be arranged next to the sixth overlay key segments 500K-2 within the first overlay key region OLKR1. The eighth overlay key segments 600K-2 are spaced apart from each other along the second direction D2.

Referring to FIG. 49 and FIG. 53, as the fifth conductive patterns 600 may be arranged while being spaced apart from each other in the first and second directions D1, D2 over the semiconductor substrate 100, a degree of overlay or a degree of alignment of the fifth conductive patterns 600 may be measured for both the first and second directions D1, D2. The seventh overlay key segments 600K-1 are spaced apart from each other along the first direction D1 which is the same as the direction in which some of the fifth conductive patterns 600 are spaced apart from each other. The eighth overlay key segments 600K-2 are spaced apart from each other along the second direction D2 which is the same as the direction in which the remaining fifth conductive patterns 600 are spaced apart from each other.

The seventh and eighth overlay key segments 600K-1, 600K-2 have a bar shape. The seventh and eighth overlay key segments 600K-1, 600K-2 may be patterns having a larger width, a larger critical line width (CD), and/or larger pitches than the fifth conductive patterns 600. The seventh and eighth overlay key segments 600K-1, 600K-2 may be seventh and eighth overlay keys providing overlay information of the fifth pattern array.

As the fifth conductive patterns 600 and the seventh and eighth overlay key segments 600K-1, 600K-2 of the fifth pattern array are formed at the same time, when the fifth conductive patterns 600 are patterned as patterns moved or displaced from the positions intended in a design, the seventh and eighth overlay key segments 600K-1, 600K-2 are patterned as patterns moved or displaced from the positions intended in the design.

By measuring positions of the seventh overlay key segments 600K-1 with respect to the fifth overlay key segments 500K-1, which are previously formed preceding patterns, it is possible to obtain overlay information or alignment information along the first direction D1 between the fifth conductive patterns 600 and the fourth conductive patterns 500, which are preceding patterns. By comparing planar shapes or images of the fifth overlay key segments 500K-1 and the seventh overlay key segments 600K-1, it is possible to measure overlay information or alignment information along the first direction D1 between the fifth conductive patterns 600 and the fourth conductive patterns 500.

By measuring positions of the eighth overlay key segments 600K-2 with respect to the sixth overlay key segments 500K-2, which are previously formed preceding patterns, it is possible to obtain overlay information or alignment information along the second direction D2 between the fifth conductive patterns 600 and the fourth conductive patterns 500, which are preceding patterns. By comparing planar shapes or images of the sixth overlay key segments 500K-2 and the eighth overlay key segments 600K-2, it is possible to measure overlay information or alignment information along the second direction D2 between the fifth conductive patterns 600 and the fourth conductive patterns 500.

Through overlay measurement, the fifth, sixth, seventh, and eighth overlay key segments 500K-1, 500K-2, 600K-1, 600K-2 provide alignment information of the fifth pattern array with respect to the fourth pattern arrays. Through overlay measurement using the fifth, sixth, seventh, and eighth overlay key segments 500K-1, 500K-2, 600K-1, 600K-2, overlay information or alignment information of the fifth conductive patterns 600 with respect to the fourth conductive patterns 500 is obtained.

Referring to FIG. 50, FIG. 51, FIG. 52, FIG. 54, and FIG. 55, the fifth pattern array including fifth conductive patterns 600, seventh overlay key segments 600K-1, and eighth overlay key segments 600K-2 are formed on a fifth dielectric layer 510 over the semiconductor substrate 100. The fifth pattern array may be formed by depositing a conductive layer on the fifth dielectric layer 510 and removing some portions of the conductive layer by a photolithography process and an etching process.

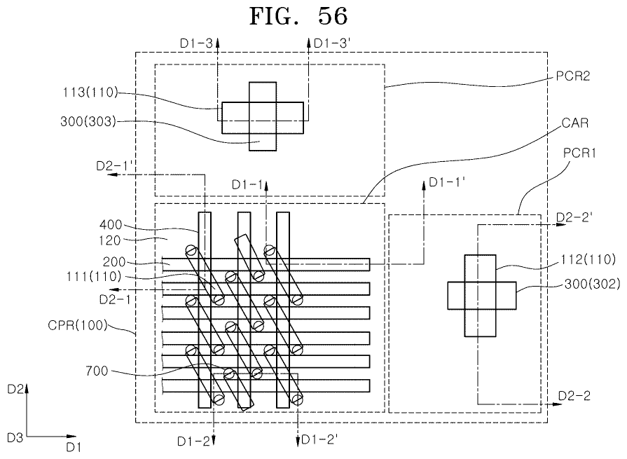

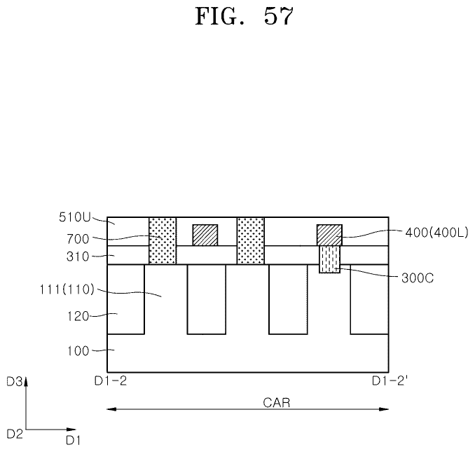

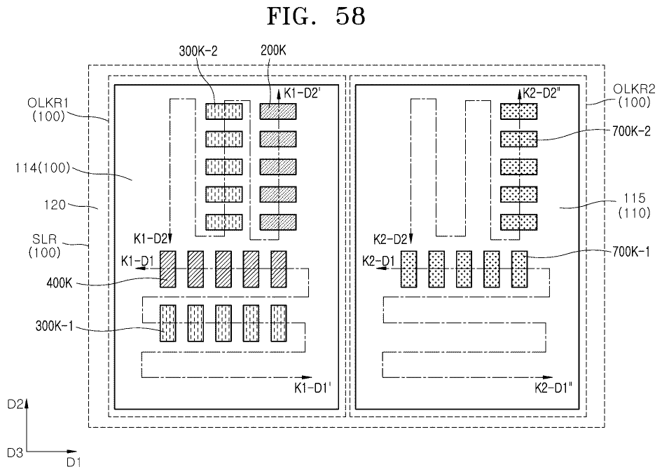

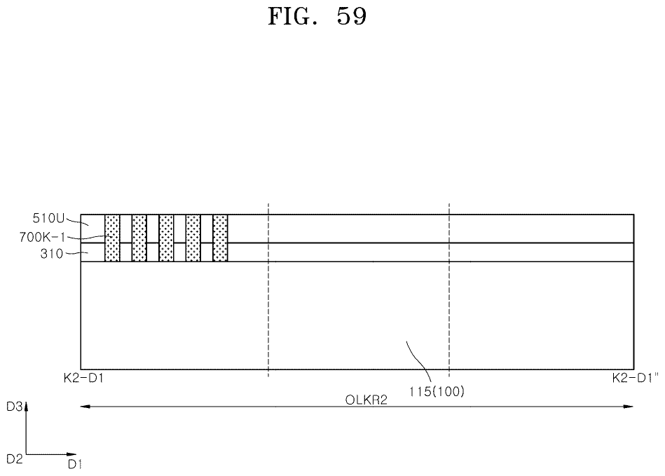

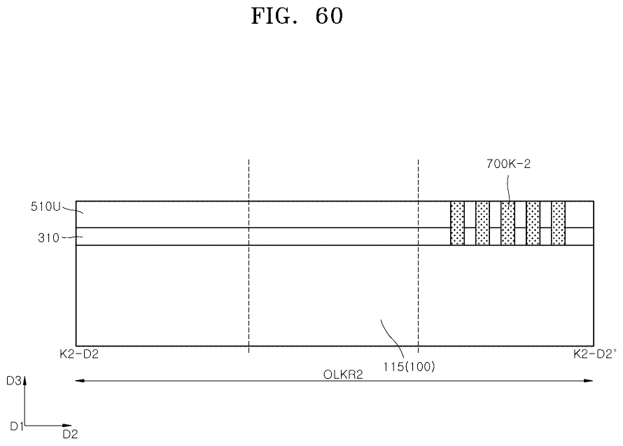

FIG. 56 through FIG. 60 are schematic diagrams illustrating a sixth pattern array of a semiconductor device according to an embodiment of the present disclosure. FIG. 56 is a schematic plan view illustrating an arrangement of sixth conductive patterns 700 in a cell array region CAR of a semiconductor device. FIG. 57 is a schematic view illustrating a cross-sectional shape along a line from D1-2 to D1-2′ in FIG. 56. FIG. 58 is a schematic plan view illustrating an arrangement of ninth overlay key segments 700K-1 and tenth overlay key segments 700K-2 of a semiconductor device. The sixth pattern array may include the sixth conductive patterns 700 of FIG. 56 and the ninth and tenth overlay key segments 700K-1 and 700K-2 of FIG. 58. FIG. 59 is a schematic view illustrating a cross-sectional shape along a line from K2-D1 to K2-D1″ in FIG. 58. FIG. 60 is a schematic view illustrating a cross-sectional shape along a line from K2-D2 to K2-D2″ in FIG. 58.

Referring to FIG. 56, FIG. 57, FIG. 58, FIG. 59, and FIG. 60, the semiconductor device may further include a sixth pattern array including sixth conductive patterns 700, ninth overlay key segments 700K-1, and tenth overlay key segments 700K-2. The third pattern array including third conductive patterns 400 and the fourth overlay key segments 400K are formed as preceding patterns, and the sixth pattern array is formed over the semiconductor substrate 100.

The ninth overlay key segments 700K-1 and the tenth overlay key segments 700K-2 are formed simultaneously with the sixth conductive patterns 700. Forming the ninth overlay key segments 700K-1, the tenth overlay key segments 700K-2, and the sixth conductive patterns 700 at the same time, allows positioning the ninth overlay key segments 700K-1, the tenth overlay key segments 700K-2, and the sixth conductive patterns 700 together within the sixth pattern array. The ninth overlay key segments 700K-1, the tenth overlay key segments 700K-2, and the sixth conductive patterns 700 are formed by pattern forming processes including a photolithography process, an etching process, and a deposition process.

Referring to FIG. 56 and FIG. 57, the sixth conductive patterns 700 may be formed to extend along the third direction D3 to pass between the third conductive patterns 400, which are preceding patterns. The sixth conductive patterns 700 may be spaced apart from each other in the first direction D1 and in the second direction D2. The sixth conductive patterns 700 may be arranged over the cell array region CAR of the semiconductor substrate 100.

Referring to FIG. 57, FIG. 59, and FIG. 60, the sixth conductive patterns 700 may be formed as connecting contacts penetrating the third dielectric layer 310 and a sixth dielectric layer 510U to connect to some portions of the first active regions 111 in the semiconductor substrate 100. The sixth dielectric layer 510U is formed as a sub-dielectric layer of the fifth dielectric layer 510 illustrated in FIGS. 43 and 44. The sixth dielectric layer 510U may include, for example, silicon oxide or silicon nitride. The sixth dielectric layer 510U is formed on the third dielectric layer 310 to cover the third conductive patterns 400. The sixth dielectric layer 510U is formed as an insulating layer for isolating (or insulating) the third conductive patterns 400.

As the ninth overlay key segments 700K-1 and the tenth overlay key segments 700K-2 are formed simultaneously with the sixth conductive patterns 700, the ninth overlay key segments 700K-1 and the tenth overlay key segments 700K-2 may pass through the third dielectric layer 310 and the sixth dielectric layer 510U, however the embodiments are not limited thereto.

Through holes are formed to pass through the sixth dielectric layer 510U and the third dielectric layer 310 and expose surfaces of some portions of the first active regions 111 in the semiconductor substrate 100. The sixth conductive patterns 700 may be formed spaced apart from each other by filling the through holes with a conductive layer and removing some portions of the conductive layer to separate the sixth conductive patterns 700 from the conductive layer for each through hole. The sixth conductive patterns 700 may be storage node contacts that connect capacitors of the cell devices 109 of FIG. 1 to the first active regions 111 in the semiconductor substrate 100. The sixth conductive patterns 700 may include a semiconductor layer such as a polysilicon layer doped with p-type impurities or n-type impurities.

Referring to FIG. 58, the ninth overlay key segments 700K-1 and the tenth overlay key segments 700K-2 may be arranged within the second overlay key region OLKR2 over the semiconductor substrate 100. The ninth overlay key segments 700K-1 may be spaced apart from each other along the first direction D1. The tenth overlay key segments 700K-2 may be spaced apart from each other along the second direction D2.

Referring to FIG. 56 and FIG. 58, as the sixth conductive patterns 700 may be arranged while being spaced apart from each other in the first and second directions D1, D2 over the semiconductor substrate 100, the degree of overlay or alignment of the sixth conductive patterns 700 may be measured for both first and second directions D1, D2. The ninth overlay key segments 700K-1 may be spaced apart from each other along the first direction D1 which is the same as the direction in which the fifth conductive patterns 700 are spaced apart from each other. The tenth overlay key segments 700K-2 may be formed spaced apart from each other along the second direction D2 which is the same as the direction in which the sixth conductive patterns 700 may be spaced apart from each other.

The ninth and tenth overlay key segments 700K-1, 700K-2 may have a bar shape. The ninth and tenth overlay key segments 700K-1, 700K-2 may be patterns having a larger width, a larger critical line width (CD), and/or larger pitches than the sixth conductive patterns 700. The ninth and tenth overlay key segments 700K-1, 700K-2 may be the ninth and tenth overlay keys providing overlay information of the sixth pattern array.

As the sixth conductive patterns 700 and the ninth and tenth overlay key segments 700K-1, 700K-2 of the sixth pattern array are formed at the same time, when the sixth conductive patterns 700 are patterned as patterns moved or displaced from the positions intended in a design, the ninth and tenth overlay key segments 700K-1, 700K-2 are patterned as patterns moved or displaced from the positions intended in the design. By measuring positions, observing planar shape, or observing planar image of the ninth overlay key segments 700K-1, overlay information or alignment information along the first direction D1 of the sixth conductive patterns 700 is obtained. By measuring positions, observing planar shape, or observing planar image of the tenth overlay key segments 700K-2, it is possible to measure overlay information or alignment information along the second direction D2 of the sixth conductive patterns 700. Through overlay measurement using the nineth and tenth overlay key segments 700K-1, 700K-2, overlay information and alignment information of the sixth pattern array and the sixth conductive patterns 700 may be measured.

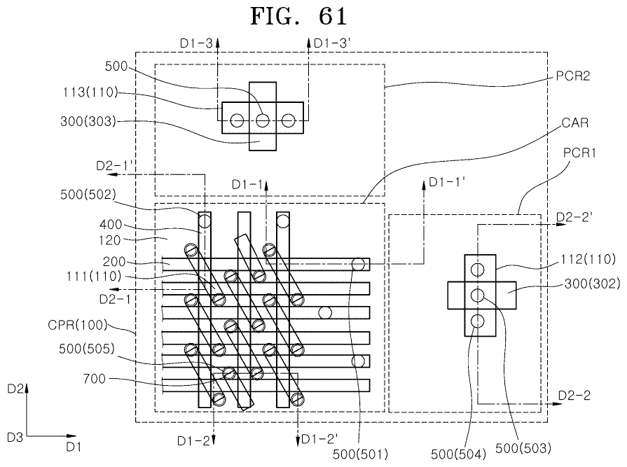

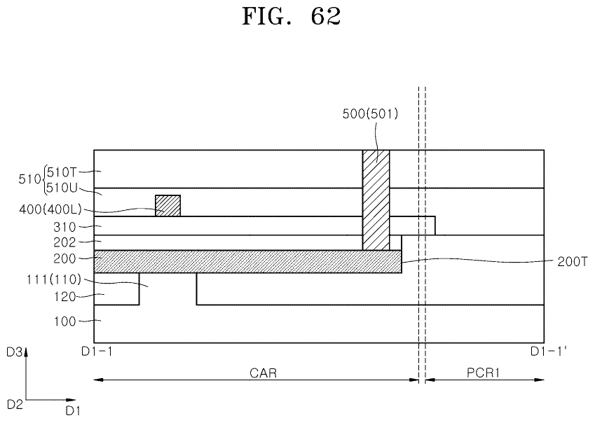

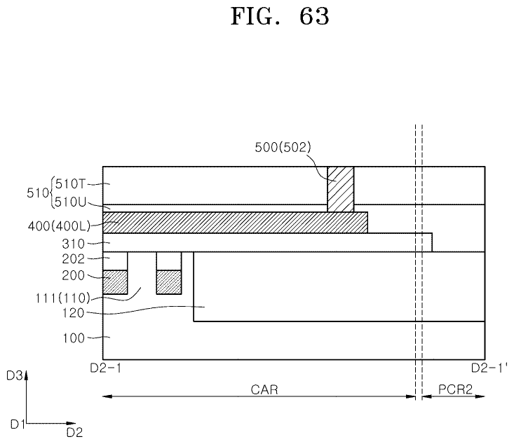

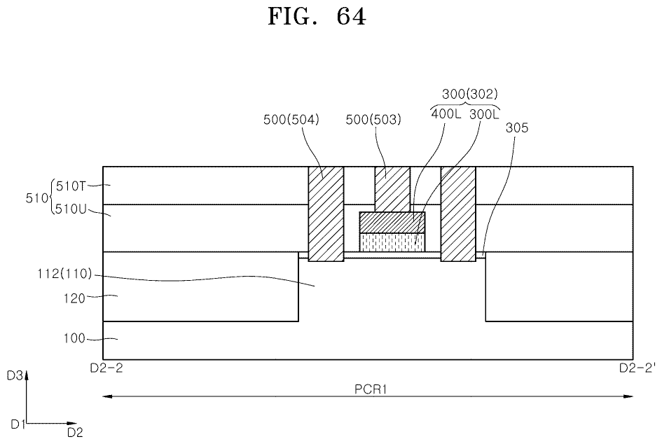

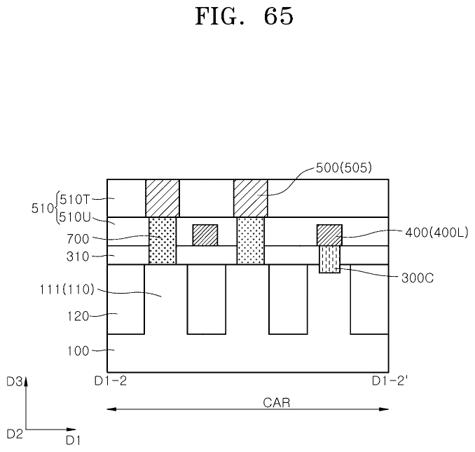

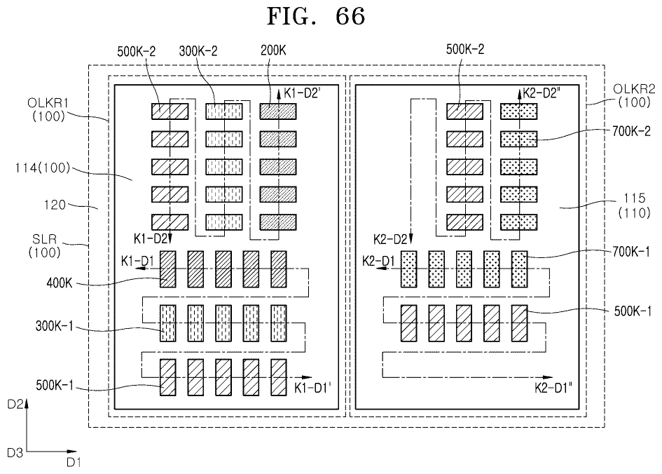

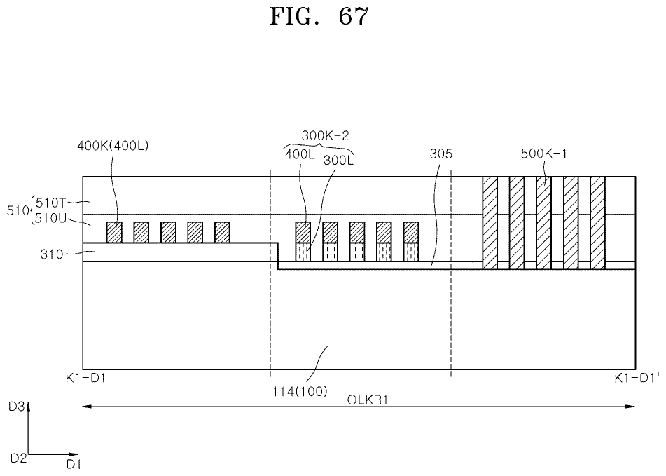

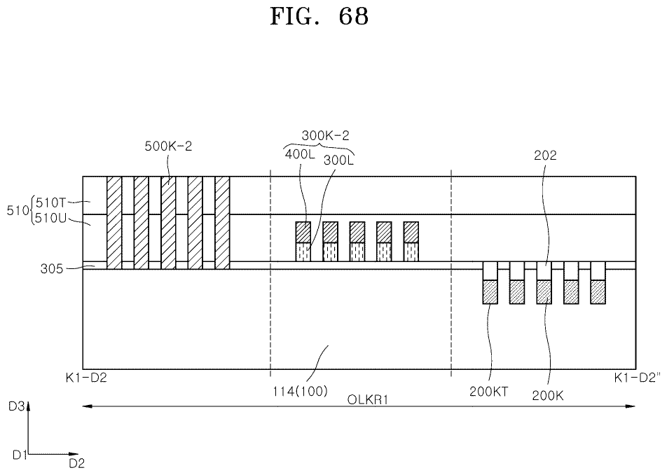

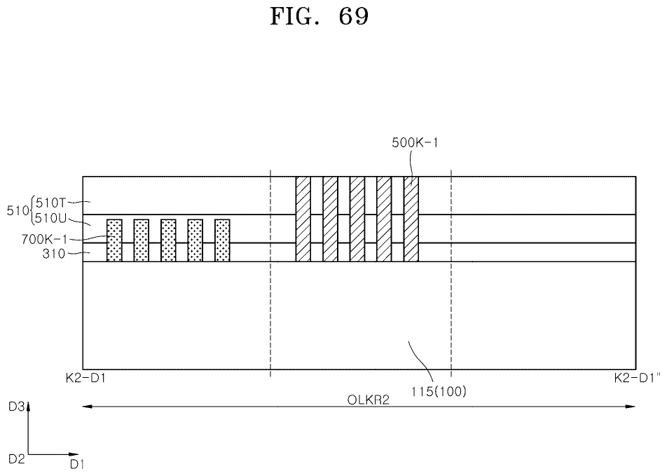

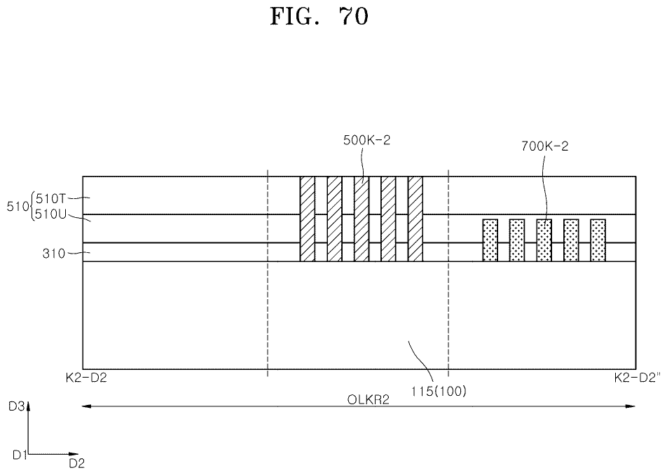

FIG. 61 through FIG. 70 are schematic diagrams illustrating a fourth pattern array of a semiconductor device according to an embodiment of the present disclosure. FIG. 61 is a schematic plan view illustrating an arrangement of fourth conductive patterns 500 in a cell array region CAR and peripheral circuit regions PCR1, PCR2 of a semiconductor device. FIG. 62 is a schematic view illustrating a cross-sectional shape along a line from D1-1 to D1-1′ in FIG. 61. FIG. 63 is a schematic view illustrating a cross-sectional shape along a line from D2-1 to D2-1′ in FIG. 61. FIG. 64 is a schematic view illustrating a cross-sectional shape along a line from D2-2 to D2-2′ in FIG. 61. FIG. 65 is a schematic view illustrating a cross-sectional shape along a line from D1-2 to D1-2′ in FIG. 61. FIG. 66 is a schematic plan view illustrating an arrangement of fifth overlay key segments 500K-1 and sixth overlay key segments 500K-2 of a semiconductor device. The fourth pattern array includes the fourth conductive patterns 500 of FIG. 61 and the fifth overlay key segments 500K-1 and sixth overlay key segments 500K-2 of FIG. 66. FIG. 67 is a schematic view illustrating a cross-sectional shape along a line from K1-D1 to K1-D1′ in FIG. 66. FIG. 68 is a schematic view illustrating a cross-sectional shape along a line from K1-D2 to K1-D2′ in FIG. 66. FIG. 69 is a schematic view illustrating a cross-sectional shape along a line from K2-D1 to K2-D1″ in FIG. 66. FIG. 70 is a schematic view illustrating a cross-sectional shape along a line from K2-D2 to K2-D2″ in FIG. 66.

Referring to FIG. 61, FIG. 62, FIG. 63, FIG. 64, FIG. 65, FIG. 66, FIG. 67, FIG. 68, FIG. 69, and FIG. 70, a fourth pattern array is formed over a semiconductor substrate 100. The fourth pattern array includes fourth conductive patterns 500, fifth overlay key segments 500K-1, and sixth overlay key segments 500K-2. As the fourth conductive patterns 500, the fifth overlay key segments 500K-1 and the sixth overlay key segments 500K-2 are formed at the same time, the fourth conductive patterns 500, the fifth overlay key segments 500K-1 and the sixth overlay key segments 500K-2 are positioned together within the fourth pattern array.

Referring to FIG. 61, FIG. 62, FIG. 63, FIG. 64, and FIG. 65, the fourth conductive patterns 500 are formed as elements that may be connected to the first, second, third, and sixth conductive patterns 200, 300, 400, 700, which are preceding patterns, and/or to portions of the semiconductor substrate 100. The fourth conductive patterns 500 may be formed as second connecting contacts that may be connected to the first, second, third, and sixth conductive patterns 200, 300, 400, 700 and/or connected to second and third active regions 112, 113 of the semiconductor substrate 100, respectively. As the first conductive patterns 200 may be formed as word lines WL of FIG. 1, the second conductive patterns 300 may be formed as peripheral gate patterns of peripheral transistors, the third conductive patterns 400 may be formed as bit lines BL of FIG. 1, and the sixth conductive patterns 700 may be formed as storage node contacts connected to capacitors of FIG. 1, the fourth conductive patterns 500 may include connection contacts respectively connected to the word lines WL, the bit lines BL, the peripheral transistors, and the storage node contacts.

Referring to FIG. 61 and FIG. 66, the fourth conductive patterns 500 are spaced apart from each other in the first and second directions D1, D2 over the semiconductor substrate 100. The fifth overlay key segments 500K-1 and the sixth overlay key segments 500K-2 may be arranged in both the first overlay key region OLKR1 and the second overlay key region OLKR2 over the semiconductor substrate 100.

The fifth overlay key segments 500K-1 may be arranged in parallel with the second overlay key segments 300K-1 and the fourth overlay key segments 400K within the first overlay key region OLKR1. The fifth overlay key segments 500K-1, the second overlay key segments 300K-1, and the fourth overlay key segments 400K may be arranged sequentially along the second direction D2 within the first overlay key region OLKR1. Additional fifth overlay key segments 500K-1 may be arranged in parallel with the ninth overlay key segments 700K-1 within the second overlay key region OLKR2. The fifth overlay key segments 500K-1 and the ninth overlay key segments 700K-1 may be sequentially arranged along the second direction D2 within the second overlay key area OLKR2. The overlay key structure may be modified such that the ninth overlay key segments 700K-1 may be arranged next to the fifth overlay key segments 500K-1 within the first overlay key area OLKR1. The fifth overlay key segments 500K-1 may be arranged spaced apart from each other along the first direction D1.

The sixth overlay key segments 500K-2 may be arranged parallel to the third overlay key segments 300K-2 and the first overlay key segments 200K within the first overlay key region OLKR1. The sixth overlay key segments 500K-2, the third overlay key segments 300K-2, and the first overlay key segments 200K may be arranged sequentially along the first direction D1. Additional sixth overlay key segments 500K-2 may be arranged parallel to the tenth overlay key segments 700K-2 within the second overlay key region OLKR2. The sixth overlay key segments 600K-1 and the tenth overlay key segments 700K-2 may be arranged sequentially along the second direction D2 within the second overlay key region OLKR2. The overlay key structure may be modified such that the tenth overlay key segments 700K-2 may be arranged next to the sixth overlay key segments 500K-2 within the first overlay key region OLKR1. The sixth overlay key segments 600K-1 are spaced apart from each other along the second direction D2.

As the fourth conductive patterns 500 and the fifth and sixth overlay key segments 500K-1, 500K-2 of the fourth pattern array are formed at the same time or simultaneously, when the fourth conductive patterns 500 are formed as patterns moved or displaced from positions intended in a design, the fifth and sixth overlay key segments 500K-1, 500K-2 are also patterned as patterns moved or displaced from the positions intended in the design.

By measuring the positions of the fifth overlay key segments 500K-1 with respect to the previously formed preceding patterns, which are the second overlay key segments 300K-1, the fourth overlay key segments 400K, and the ninth overlay key segments 700K-1, it is possible to measure overlay information or alignment information along the first direction D1 between the fourth conductive patterns 500 and the second conductive patterns 300 as well as overlay information or alignment information along the first direction D1 between the fourth conductive patterns 500 and the third conductive patterns 400, and overlay information or alignment information along the first direction D1 between the fourth conductive patterns 500 and the sixth conductive patterns 700. The second, third, and sixth conductive patterns 300, 400, 700 are preceding patterns for the fourth conductive patterns 500.

By comparing planar shapes or images of the fourth overlay key segments 400K with respect to the second overlay key segments 300K-1, the fourth overlay key segments 400K, and the ninth overlay key segments 700K-1, it is possible to measure overlay information or alignment information along the first direction D1 between the fourth conductive patterns 500 and the second conductive patterns 300, the third conductive patterns 400, and the sixth conductive patterns 700.

By measuring positions of the sixth overlay key segments 500K-2 with respect to the previously formed preceding patterns, which are the third overlay key segments 300K-2, the first overlay key segments 200K, and the tenth overlay key segments 700K-2, it is possible to measure overlay information or alignment information along the second direction D2 between the fourth conductive patterns 500 and the preceding patterns, which are the second conductive patterns 300, the first conductive patterns 200, and the sixth conductive patterns 700.

Through overlay measurement using the first, second, third, fourth, fifth, sixth, ninth, and tenth overlay key segments 200K, 300K-1, 300K-2, 400K, 500K-1, 500K-2, 700K-1, 700K-2, alignment information of the fourth pattern array to the first, second, third, and sixth pattern arrays may be provided. Through overlay measurement using the first, second, third, fourth, fifth, sixth, ninth, and tenth overlay key segments 200K, 300K-1, 300K-2, 400K, 500K-1, 500K-2, 700K-1, 700K-2, overlay information or alignment information of the fourth conductive patterns 500 with respect to the first, second, third, and sixth conductive patterns 200, 300, 400, 700 may be measured or obtained. The overlay information or alignment information may help prevent the fourth conductive patterns 500 from being undesirably misaligned with respect to the first, second, third, and sixth conductive patterns 200, 300, 400, 700.

Referring to FIG. 62, FIG. 63, FIG. 64, FIG. 65, FIG. 67, FIG. 68, FIG. 69, and FIG. 70, the fourth pattern array including the fourth conductive patterns 500, the fifth overlay key segments 500K-1, and the sixth overlay key segments 500K-2 may be formed over the sixth pattern array over a semiconductor substrate 100. A seventh dielectric layer 510T may cover the sixth conductive patterns 700, ninth overlay key segments 700K-1, and tenth overlay key segments 700K-2 on the sixth dielectric layer 510U over the semiconductor substrate 100. The sixth dielectric layer 510U and the seventh dielectric layer 510T form the fifth dielectric layer 510 and are sub-layers of the fifth dielectric layer 510. The sixth dielectric layer 510T may include, for example, silicon oxide or silicon nitride.

Through holes are formed to pass through the fifth dielectric layer 510. A conductive layer is formed to fill the through holes. A portion of the conductive layer is removed to separate filled portions of the conductive layer from each other by the through holes. Accordingly, the fourth pattern array is formed to include the fourth conductive patterns 500, the fifth overlay key segments 500K-1, and the sixth overlay key segments 500K-2.

Referring to FIG. 61 and FIG. 62, third sub-conductive patterns 501 of the fourth conductive patterns 500 are formed to pass through the seventh dielectric layer 510T, the sixth dielectric layer 510U, the third dielectric layer 310, and the first dielectric layer 202, and to be connected to the first conductive patterns 200 embedded in the semiconductor substrate 100.

Referring to FIG. 61 and FIG. 63, fourth sub-conductive patterns 502 of the fourth conductive patterns 500 are formed to pass through the seventh dielectric layer 510T and the sixth dielectric layer 510U of the fifth dielectric layer 510, and to be connected to the third conductive patterns 400 formed over the semiconductor substrate 100.

Referring to FIG. 61 and FIG. 64, fifth sub-conductive pattern 503 of the fourth conductive patterns 500 is formed to pass through the seventh dielectric layer 510T and the sixth dielectric layer 510U of the fifth dielectric layer 510, and to be connected to the second conductive pattern 300 formed over the semiconductor substrate 100. Sixth sub-conductive pattern 504 of the fourth conductive patterns 50 is formed to pass through the fifth dielectric layer 510 and the fourth dielectric layer 305, and to be connected to an active region 110, such as a second active region 112 in the semiconductor substrate 100.

Referring to FIG. 61 and FIG. 65, eleventh sub-conductive patterns 505 of the fourth conductive patterns 500 are formed to overlap and connect to the sixth conductive patterns 700 over the semiconductor substrate 100 by penetrating the seventh dielectric layer 510T. The eleventh sub-conductive patterns 505 may be electrically connected to some portions of the first active regions 111 of the semiconductor substrate 100 through the sixth conductive patterns 700.

Referring to FIG. 61, FIG. 62, FIG. 63, FIG. 64, and FIG. 65, objects or targets to which the fourth conductive patterns 500 are connected are the first conductive patterns 200, the third conductive patterns 400, the second conductive patterns 300, the second active regions 112 of the semiconductor substrate 100, and the sixth conductive patterns 700. Depths or thicknesses of the fourth conductive patterns 500 extending in the third direction D3 may vary depending on the objects to which the fourth conductive patterns 500 are connected.

Referring to FIG. 66, FIG. 67, FIG. 68, FIG. 69, and FIG. 70, the fifth overlay key segments 500K-1 and the sixth overlay key segments 500K-2 are formed both in the first overlay key region OLKR1 and the second overlay key region OLKR2 of the semiconductor substrate 100 simultaneously with the fourth conductive patterns 500 of FIG. 62, FIG. 63, FIG. 64, and FIG. 65. As the fourth conductive patterns 500, the fifth overlay key segments 500K-1, and the sixth overlay key segments 500K-2 are formed at the same time, the fifth overlay key segments 500K-1 and the sixth overlay key segments 500K-2 have a depth or thickness extending in the third direction D3 that is substantially the same as one of the fourth conductive patterns 500.

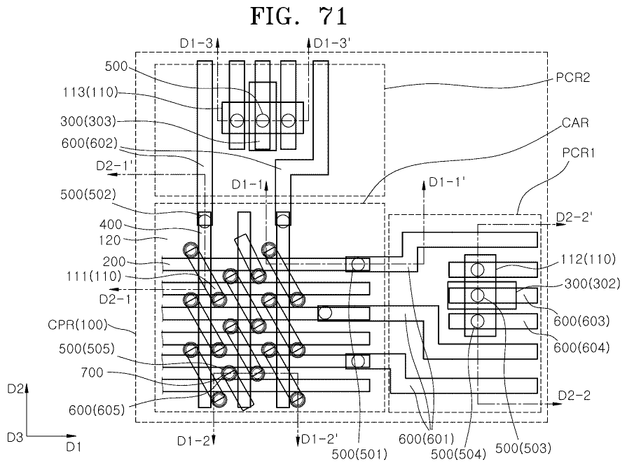

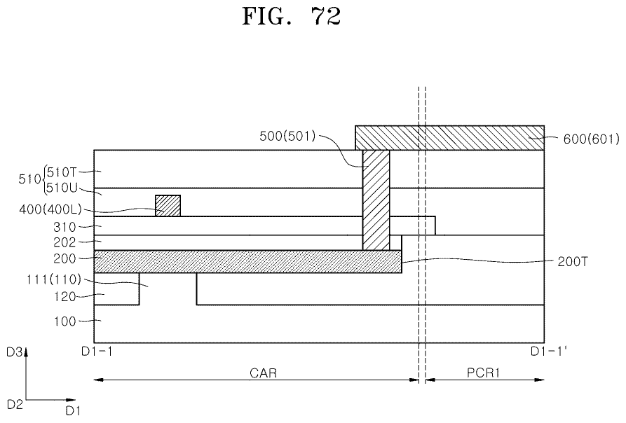

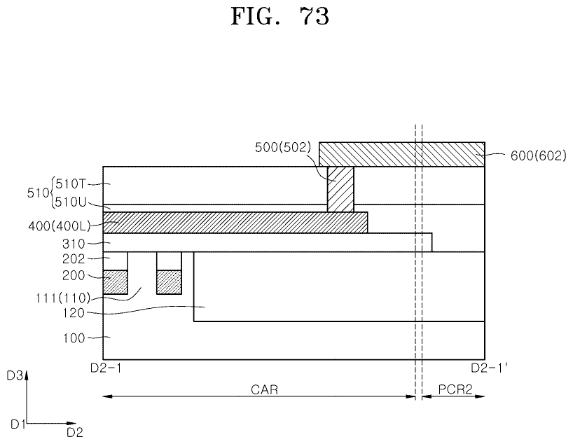

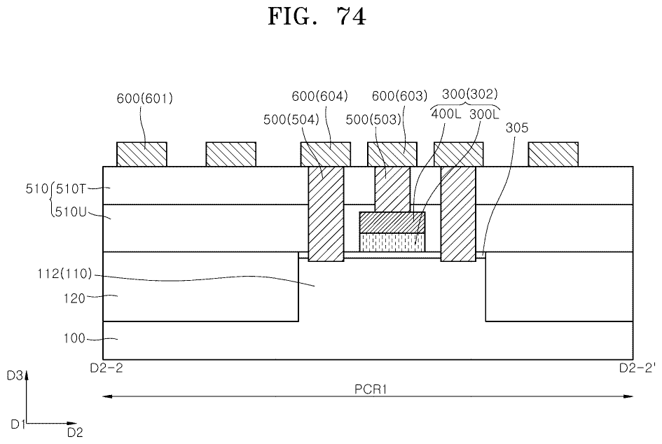

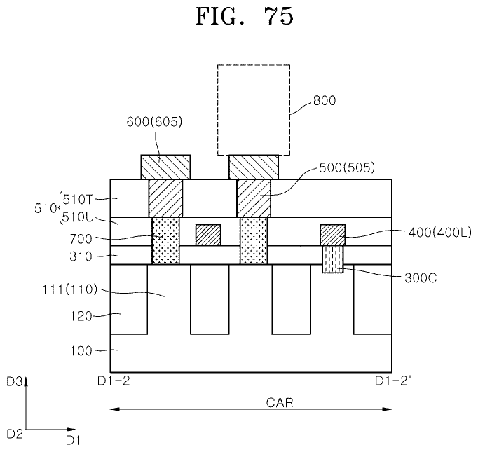

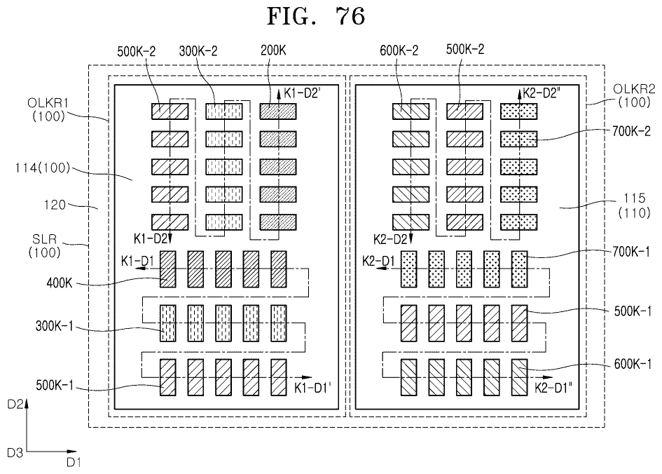

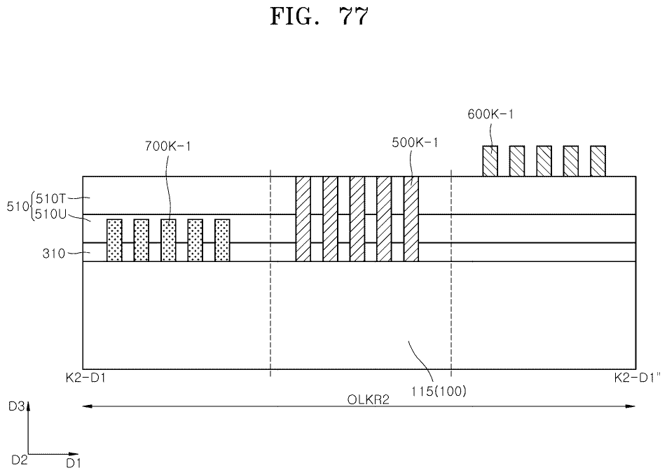

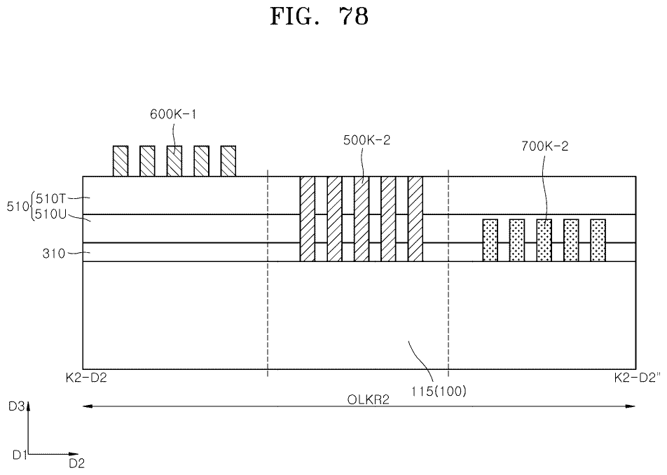

FIG. 71 through 78 are schematic diagrams illustrating a fifth pattern array of a semiconductor device according to an embodiment of the present disclosure. FIG. 71 is a schematic plan view illustrating an arrangement of fifth conductive patterns 600 in a chip region CPR of a semiconductor device. FIG. 72 is a schematic view illustrating a cross-sectional shape along a line from D1-1 to D1-1′ in FIG. 71. FIG. 73 is a schematic view illustrating a cross-sectional shape along a line from D2-1 to D2-1′ in FIG. 71. FIG. 74 is a schematic view illustrating a cross-sectional shape along a line from D2-2 to D2-2′ in FIG. 71. FIG. 75 is a schematic view illustrating a cross-sectional shape along a line from D1-2 to D1-2′ in FIG. FIG. 76 is a schematic plan view illustrating an arrangement of seventh overlay key segments 600K-1 and eighth overlay key segments 600K-2 of a semiconductor device. The fifth pattern array includes the fifth conductive patterns 600 of FIG. 71 and the seventh overlay key segments 600K-1 and the eighth overlay key segments 600K-2 of FIG. 76. FIG. 77 is a schematic view illustrating a cross-sectional shape along a line from K2-D1 to K2-D1″ in FIG. 76. FIG. 78 is a schematic view illustrating a cross-sectional shape along a line from K2-D2 to K2-D2″ in FIG. 76.

Referring to FIG. 71, FIG. 72, FIG. 73, FIG. 74, FIG. 75, FIG. 76, FIG. 77, and FIG. 78, a fifth pattern array may be formed over the fourth pattern array of a semiconductor substrate 100. The fifth pattern array may be formed on the fifth dielectric layer 510 of the semiconductor substrate 100. The seventh overlay key segments 600K-1 and the eighth overlay key segments 600K-2 may be formed simultaneously with the fifth conductive patterns 600. Forming the fifth conductive patterns 600, the seventh overlay key segments 600K-1, and the eighth overlay key segments 600K-2 at the same time, allows the fifth conductive patterns 600, the seventh overlay key segments 600K-1, and the eighth overlay key segments 600K-2 to be positioned together within the fifth pattern array. The seventh overlay key segments 600K-1, the eighth overlay key segments 600K-2, and the fifth conductive patterns 600 may be formed by one identical pattern forming process including, for example, a photolithography process, an etching process, a deposition process, etc.

Referring to FIG. 71, FIG. 72, FIG. 73, FIG. 74, and FIG. 75, the fifth conductive patterns 600 may be connected to the fourth conductive patterns 500 which are the preceding patterns, respectively. The fifth conductive patterns 600 are electrically connected to the first, second, third, and sixth conductive patterns 200, 300, 400, 700, respectively, by being connected to the fourth conductive patterns 500, and/or may be electrically connected to the second and third active regions 112, 113 of the semiconductor substrate 100, respectively. The fourth conductive patterns 500 may be connecting contacts that connect the fifth conductive patterns 600 to the first, second, third, and sixth conductive patterns 200, 300, 400, 600, and some portions of the semiconductor substrate 100.

Referring to FIG. 71 and FIG. 72, the seventh sub-conductive patterns 601 of the fifth conductive patterns 600 may extend along the first direction D1 over the semiconductor substrate 100 and may be spaced apart from each other in the second direction D2. The seventh sub-conductive patterns 601 may be respectively connected to the third sub-conductive patterns 501 of the fourth conductive patterns 500. The seventh sub-conductive patterns 601 may be connected to the first conductive patterns 200 through the third sub-conductive patterns 501. The seventh sub-conductive patterns 601 may be wirings connected to the word lines WL of FIG. 1.

Referring to FIG. 71 and FIG. 73, the eighth sub-conductive patterns 602 of the fifth conductive patterns 600 may extend in the second direction D2 over the semiconductor substrate 100 and may be spaced apart from each other in the first direction D1. The eighth sub-conductive patterns 602 may be connected to the fourth sub-conductive patterns 502 of the fourth conductive patterns 500. The eighth sub-conductive patterns 602 may be connected to the third conductive patterns 400 through the fourth sub-conductive patterns 502. The eighth sub-conductive patterns 602 may be wirings connected to the bit lines BL of FIG. 1.

Referring to FIG. 71 and FIG. 74, the ninth sub-conductive pattern 603 of the fifth conductive pattern 600 may be connected to the fifth sub-conductive pattern 503 of the fourth conductive patterns 500. The ninth sub-conductive pattern 603 may be connected to the first sub-conductive pattern 302 of the second conductive patterns 300 through the fifth sub-conductive pattern 503. The ninth sub-conductive pattern 603 may be a wiring connected to a peripheral gate pattern of a peripheral transistor. The peripheral gate pattern includes the first sub-conductive pattern 302.

The tenth sub-conductive patterns 604 of the fifth conductive patterns 600 may be respectively connected to the sixth sub-conductive patterns 504 of the fourth conductive patterns 500. The tenth sub-conductive patterns 604 may be connected to the second active region 112 of the active regions 110 of the semiconductor substrate 100 through the sixth sub-conductive patterns 504. The ninth and tenth sub-conductive patterns 603, 604 may be wirings connected to a peripheral transistor including the second active region 112 and the first sub-conductive pattern 302.

Referring to FIG. 71 and FIG. 75, the twelfth sub-conductive patterns 605 of the fifth conductive patterns 600 may be respectively connected to the eleventh sub-conductive patterns 505 of the fourth conductive patterns 500. As the twelfth sub-conductive patterns 605 are connected while overlapping the eleventh sub-conductive patterns 505, the twelfth sub-conductive patterns 605 may be connected to the sixth conductive patterns 700 through the eleventh sub-conductive patterns 505. A stack structure including the twelfth sub-conductive pattern 605, the eleventh sub-conductive pattern 505, and the sixth conductive pattern 700 may electrically connect a portion of the first active region 111 of the semiconductor substrate 100 to a capacitor 800.

Referring to FIG. 76, the seventh overlay key segments 600K-1 and the eighth overlay key segments 600K-2 may be arranged within the second overlay key region OLKR2 over the semiconductor substrate 100. The seventh overlay key segments 600K-1 may be arranged parallel to the fifth overlay key segments 500K-1 and the ninth overlay key segments 700K-1. The seventh overlay key segments 600K-1, the fifth overlay key segments 500K-1, and the ninth overlay key segments 700K-1 may be arranged sequentially along the second direction D2. The seventh overlay key segments 600K-1 are spaced apart from each other along the first direction D1.

The eighth overlay key segments 600K-2 may be arranged parallel to the sixth overlay key segments 500K-2 and the tenth overlay key segments 700K-2. The eighth overlay key segments 600K-2, the sixth overlay key segments 500K-2, and the tenth overlay key segments 700K-2 may be arranged sequentially along the first direction D1. The eighth overlay key segments 600K-2 are spaced apart from each other along the second direction D2.

Referring to FIG. 71 and FIG. 76, as the fifth conductive patterns 600 may be arranged while being spaced apart from each other in the first and second directions D1, D2 over the semiconductor substrate 100, the seventh overlay key segments 600K-1 are spaced apart from each other along the first direction D1 which is the same as a direction in which the fifth conductive patterns 600 are spaced apart from each other. The eighth overlay key segments 600K-2 are spaced apart from each other along the second direction D2 which is the same as another direction in which the fifth conductive patterns 600 are spaced apart from each other.

As the fifth conductive patterns 600 and the seventh and eighth overlay key segments 600K-1, 600K-2 of the fifth pattern array are formed at the same time, when the fifth conductive patterns 600 are formed as patterns moved or displaced from positions intended in a design, the seventh and eighth overlay key segments 600K-1, 600K-2 are also patterned with patterns moved or displaced from positions intended in the design.

By measuring positions of the seventh overlay key segments 600K-1 with respect to the fifth overlay key segments 500K-1, which are previously formed preceding patterns, it is possible to measure overlay information or alignment information along the first direction D1 between the fifth conductive patterns 600 and the fourth conductive patterns 500, which are previously formed preceding patterns. By measuring positions of the eighth overlay key segments 600K-2 relative to the sixth overlay key segments 500K-2, which are previously formed preceding patterns, it is possible to measure overlay information or alignment information along the second direction D2 between the fifth conductive patterns 600 and the fourth conductive patterns 500, which are previously formed preceding patterns.

In this way, through overlay measurement, the fifth, sixth, seventh, and eighth overlay key segments 500K-1, 500K-2, 600K-1, 600K-2 provide alignment information of the fifth pattern array with respect to the fourth pattern arrays. Through overlay measurement using the fifth, sixth, seventh, and eighth overlay key segments 500K-1, 500K-2, 600K-1, 600K-2, overlay information or alignment information of the fifth conductive patterns 600 with respect to the fourth conductive patterns 500 is obtained or measured.

Referring to FIG. 72, FIG. 73, FIG. 74, FIG. 75, FIG. 77, and FIG. 78, the fifth pattern array including the fifth conductive patterns 600, the seventh overlay key segments 600K-1, and the eighth overlay key segments 600K-2 is formed over the fifth dielectric layer 510 of the semiconductor substrate 100. The fifth pattern array may be formed by depositing a conductive layer on the fifth dielectric layer 510 and removing some portions of the conductive layer by a photolithography process and an etching process.

Referring to FIG. 71, FIG. 72, FIG. 73, FIG. 74, and FIG. 75, the fourth conductive patterns 500 are formed as elements that connect the fifth conductive patterns 600 to the first conductive patterns 200, the third conductive patterns 400, the second conductive patterns 300, and the sixth conductive patterns 700, respectively. When the fourth conductive patterns 500 are misaligned with respect to the fifth conductive patterns 600, the first conductive patterns 200, the third conductive patterns 400, the second conductive patterns 300, or/and the sixth conductive patterns 700, defects may occur in which the fifth conductive patterns 600 are not electrically connected to the first conductive patterns 200, the third conductive patterns 400, the second conductive patterns 300, or/and the sixth conductive patterns 700. When the fourth conductive patterns 500 are misaligned with respect to the fifth conductive patterns 600, the first conductive patterns 200, the third conductive patterns 400, the second conductive patterns 300, or/and the sixth conductive patterns 700, a defect such as a punch through in which the fourth conductive patterns 500 are electrically connected to the wrong elements may occur.

Information about alignment of the fourth conductive patterns 500 with respect to the fifth conductive patterns 600, the first conductive patterns 200, the third conductive patterns 400, the second conductive patterns 300, and/or the sixth conductive patterns 700 are obtained through overlay measurement or alignment measurement for the first, second, third, fourth, fifth, sixth, seventh, eighth, ninth, and tenth overlay key segments 200K, 300K-1, 300K-2, 400K, 500K-1, 500K-2, 600K-1, 600K-2, 700K-1, 700K-2 presented in FIG. 76.

Referring to FIG. 76, the fourth overlay key segments 400K, the second overlay key segments 300K-1, and the fifth overlay key segments 500K-1 may be designed to be formed while being aligned with each other along the second direction D2. The seventh overlay key segments 600K-1, the fifth overlay key segments 500K-1, and the ninth overlay key segments 700K-1 may be designed to be formed while being aligned with each other along the second direction D2. The sixth overlay key segments 500K-2, the third overlay key segments 300K-2, and the first overlay key segments 200K may be designed to be formed while being aligned with each other along the first direction D1. The eighth overlay key segments 600K-2, the sixth overlay key segments 500K-2, and the ninth overlay key segments 700K-1 may be designed to be formed while being aligned with each other along the first direction D1.

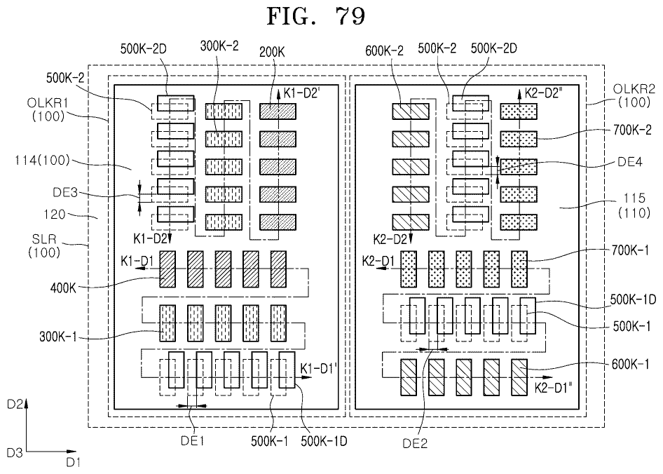

FIG. 79 is a schematic diagram illustrating measurement of alignment information in a semiconductor device according to an embodiment of the present disclosure.

Referring to FIG. 71 and FIG. 79, when the fourth conductive patterns 500 are relatively moved or displaced with respect to the fifth conductive patterns 600, the first conductive patterns 200, the third conductive patterns 400, the second conductive patterns 300, and/or the sixth conductive patterns 700, the fifth overlay key segments 500K-1 and the sixth overlay key segments 500K-2 are formed at moved positions as displaced fifth overlay key segments 500K-1D and displaced sixth overlay key segments 500K-2D.

By overlay measuring an overlay key structure presented in FIG. 79, it is possible to measure a positional deviation DE1 of the displaced fifth overlay key segments 500K-1D with respect to the fourth overlay key segments 400K and the second overlay key segments 300K-1 in the first direction D1. As each of the fourth overlay key segments 400K, the second overlay key segments 300K-1, and the displaced fifth overlay key segments 500K-1D is configured as a bar shape that is spaced apart from each other along the first direction D1, it is possible to measure the positional deviation DE1 while effectively excluding the influence of deformation of the segments' shapes.

Additional positional deviation DE2 of the displaced fifth overlay key segments 500K-1D with respect to the seventh overlay key segments 600K-1 and the ninth overlay key segments 700K-1 in the first direction D1 may be measured. A positional deviation DE3 of the displaced sixth overlay key segments 500K-2D with respect to the third overlay key segments 300K-2 and the first overlay key segments 200K in the second direction D2 may be measured. A positional deviation DE4 of the displaced sixth overlay key segments 500K-2D with respect to the eighth overlay key segments 600K-2 and the ninth overlay key segments 700K-1 in the second direction D2 may be measured.

By measuring the positional deviations DE1, DE2, DE3, DE4, information about alignment of the fourth conductive patterns 500 with respect to the fifth conductive patterns 600, the first conductive patterns 200, the third conductive patterns 400, the second conductive patterns 300, and/or the sixth conductive pattern 700 may be measured or obtained. By measuring the positional deviations DE1, DE2, DE3, DE4, information about alignment of the fourth pattern array with respect to the first, second, third, fifth, and sixth pattern arrays may be obtained. By feeding back the alignment information to processes of designing and forming the fourth pattern array including the fourth conductive patterns 500, misalignment of the fourth pattern array including the fourth conductive patterns 500 may be suppressed.

A method of manufacturing a semiconductor device according to an embodiment of present disclosure includes forming a first pattern array including first conductive patterns 200 and first overlay key segments 200K over a semiconductor substrate 100, as illustrated in FIG. 9, FIG. 10, FIG. 11, FIG. 12, and FIG. 13. The method may include forming a second pattern array including second conductive patterns 300, second overlay key segments 300K-1, and third overlay key segments 300K-2 over the semiconductor substrate 100. The method may include forming a third pattern array including third conductive patterns 400 and fourth overlay key segments 400K, as illustrated in FIG. 36, FIG. 37, FIG. 38, FIG. 39, FIG. 40, and FIG. 41. The method may include forming a fourth pattern array including fourth conductive patterns 500, fifth overlay key segments 500K-1, and sixth overlay key segments 500K-2, as illustrated in FIG. 42, FIG. 43, FIG. 44, FIG. 45, FIG. 46, FIG. 47, and FIG. 48.

The method may further include forming a fifth pattern array including fifth conductive patterns 600, seventh overlay key segments 600K-1, and eighth overlay key segments 600K-2, as illustrated in FIG. 49, FIG. 50, FIG. 51, FIG. 52, FIG. 53, FIG. 54, and FIG. 55. The method may further include forming a sixth pattern array including sixth conductive patterns 700, ninth overlay key segments 700K-1, and tenth overlay key segments 700K-2, as illustrated in FIG. 56, FIG. 57, FIG. 58, FIG. 59, and FIG. 60.

The inventive concept has been disclosed in conjunction with some embodiments as described above. Those skilled in the art will appreciate that various modifications, additions and substitutions are possible, without departing from the scope of the present disclosure. Accordingly, the embodiments disclosed in the present specification should be considered from not a restrictive standpoint but an illustrative standpoint. The scope of the inventive concept is not limited to the above descriptions but defined by the accompanying claims, and all distinctive features in the equivalent scope should be construed as being included in the inventive concept. Furthermore, the embodiments may be combined to form additional embodiments.

What is claimed is:

1. A semiconductor device comprising:
a first pattern array including first conductive patterns and first overlayer key segments formed over a semiconductor substrate;
a second pattern array including second conductive patterns, second overlay key segments, and third overlay key segments;
a third pattern array including third conductive patterns and fourth overlay key segments; and
a fourth pattern array including fourth conductive patterns, fifth overlay key segments, and sixth overlay key segments,
wherein the first, second, third, fourth, fifth, and sixth overlay key segments provide alignment of the fourth conductive patterns relative to the first, second, and third conductive patterns.

2. The semiconductor device of claim 1,
wherein the first conductive patterns extend in a first direction and are spaced apart from each other along a second direction intersecting the first direction, and the first overlayer key segments are spaced apart from each other along the second direction,
wherein the second overlay key segments are spaced apart from each other along the first direction, and the third overlay key segments are spaced apart from each other along the second direction,
wherein the third conductive patterns extend in the second direction and are spaced apart from each other along the first direction, and the fourth overlay key segments are spaced apart from each other along the first direction, and
wherein each of the fourth conductive patterns is connected to the first, second, and third conductive patterns, and a portion of the semiconductor substrate, the fifth overlay key segments are spaced apart from each other along the first direction, and the sixth overlay key segments are spaced apart from each other along the second direction.

3. The semiconductor device of claim 2,
wherein the semiconductor substrate includes a cell array region, a peripheral circuit region and an overlay key region,
wherein the first conductive patterns are located over the cell array region, and the second conductive patterns are located over the peripheral circuit region, and
wherein the first, second, third, fourth, fifth, and sixth overlay key segments are located over the overlay key region.

4. The semiconductor device of claim 3,
wherein one of the second conductive patterns is spaced apart from the cell array region in the first direction, and
wherein another of the second conductive patterns is spaced apart from the cell array region in the second direction.

5. The semiconductor device of claim 1, wherein the first conductive patterns and the first overlay key segments are positioned to be embedded in the semiconductor substrate.

6. The semiconductor device of claim 1, wherein the third conductive patterns cross over the first conductive patterns.

7. The semiconductor device of claim 1,
wherein the first overlay key segments are formed at the same time as the first conductive patterns in the first pattern array,
wherein the second and third overlay key segments are formed at the same time as the second conductive patterns in the second pattern array,
wherein the fourth overlay key segments are formed at the same time as the third conductive patterns in the third pattern array, and
wherein the fifth and sixth overlay key segments are formed at the same time as the fourth conductive patterns in the fourth pattern array.

8. The semiconductor device of claim 1, wherein the first overlay key segments have a bar feature.

9. The semiconductor device of claim 2, wherein the fourth conductive patterns are spaced apart from each other along the first direction and the second direction.

10. The semiconductor device of claim 2, further comprising a fifth pattern array including fifth conductive patterns, seventh overlay key segments, and eighth overlay key segment,
wherein the fifth conductive patterns are connected to the fourth conductive patterns, the seventh overlay key segments are spaced apart from each other along the first direction, and the eighth overlay key segments are spaced apart from each other along the second direction.

11. The semiconductor device of claim 10,
wherein some of the fifth conductive patterns extend in the first direction and are spaced apart from each other in the second direction, and
wherein other ones of the fifth conductive patterns extend in the second direction and are spaced apart from each other in the first direction.

12. The semiconductor device of claim 10, wherein the fourth conductive pattern includes a connection contact, and
wherein the connection contact connects the fifth conductive pattern to the first, second, third conductive patterns or a portion of the semiconductor substrate.

13. The semiconductor device of claim 1,
wherein the first conductive patterns include word lines,
wherein the second conductive patterns include gate patterns of transistors,
wherein the third conductive patterns include bit lines, and
wherein the fourth conductive patterns include connection contacts connected to the word lines, the bit lines, and the transistors.

14. A semiconductor device comprising:
a first pattern array including first conductive patterns and first overlayer key segments formed over a semiconductor, the first conductive patterns extending in a first direction and spaced apart from each other along a second direction intersecting the first direction, and the first overlay key segments spaced apart from each other along the second direction;
a second pattern array including second conductive patterns, second overlay key segments and third overlay key segments, the second overlay key segments spaced apart from each other along the first direction, and the third overlay key segments spaced apart from each other along the second direction;
a third pattern array including third conductive patterns and fourth overlay key segments, the third conductive patterns extending in the second direction and spaced apart from each other along the first direction, and the fourth overlay key segments spaced apart from each other along the first direction;
a sixth pattern array including sixth conductive patterns, ninth overlay key segments, and tenth overlay key segments, the sixth conductive patterns passing between the third conductive patterns and connecting to some portions of the semiconductor substrate, the ninth overlay key segments spaced apart from each other along the first direction, and the tenth overlay key segments spaced apart from each other along the second direction; and
a fourth pattern array including fourth conductive patterns, fifth overlay key segments, and sixth overlay key segments, each of the fourth conductive patterns connected to the first, second, third, and sixth conductive patterns and a portion of the semiconductor substrate, the fifth overlay key segments spaced apart from each other along the first direction, and the sixth overlay key segments spaced apart from each other along the second direction,
wherein the first, second, third, fourth, fifth, sixth, ninth, and tenth overlay key segments provide alignment of the fourth conductive patterns relative to the first, second, third, and sixth conductive patterns.

15. The semiconductor device of claim 14,
wherein the semiconductor substrate includes a cell array region, a peripheral circuit region, and an overlay key region,
wherein the first conductive patterns are located over the cell array region, the second conductive patterns are located over the peripheral circuit region, the third conductive patterns cross over the first conductive patterns, and the sixth conductive patterns are located over the cell array region, and
wherein the first, second, third, fourth, fifth, sixth, ninth, and tenth overlay key segments are located over the overlay key region.

16. The semiconductor device of claim 14,
wherein one of the second conductive patterns is spaced apart from the cell array region in the first direction, and
wherein another of the second conductive patterns is spaced apart from the cell array region in the second direction.

17. The semiconductor device of claim 14, wherein the first conductive patterns and the first overlay key segments are positioned to be embedded in the semiconductor substrate.

18. The semiconductor device of claim 14,
wherein the first overlay key segments are formed at the same time as the first conductive patterns in the first pattern array,
wherein the second and third overlay key segments are formed at the same time as the second conductive patterns in the second pattern array,
wherein the fourth overlay key segments are formed at the same time as the third conductive patterns in the third pattern array,
wherein the fifth and sixth overlay key segments are formed at the same time as the fourth conductive patterns in the fourth pattern array, and
wherein the ninth and tenth overlay key segments are formed at the same time as the sixth conductive patterns in the sixth pattern array.

19. The semiconductor device of claim 14, wherein the fourth conductive patterns are spaced apart from each other along the first direction and the second direction.

20. A method of manufacturing a semiconductor device, the method comprising:
forming a first pattern array over a semiconductor substrate, the first pattern array including first conductive patterns and first overlayer key segments;
forming a second pattern array including second conductive patterns, second overlay key segments and third overlay key segments;
forming a third pattern array including third conductive patterns and fourth overlay key segments; and
forming a fourth pattern array including fourth conductive patterns, fifth overlay key segments, and sixth overlay key segments,
wherein the first, second, third, fourth, fifth, and sixth overlay key segments provide alignment of the fourth conductive patterns relative to the first, second, and third conductive patterns.
